(19) United States
(12) Patent Application Publication
(10) Pub. No.: US 2026/0231510 A1
(43) Pub. Date: Aug. 6, 2026

(54) CONTACTS IN SEMICONDUCTOR DEVICES AND METHODS OF FORMING THE SAME

(71) Applicant: Taiwan Semiconductor Manufacturing Co., Ltd., Hsinchu (TW)

(72) Inventors: Chi-Nan Wu, Taichung (TW); Ting-Gang Chen, Taipei (TW)

(21) Appl. No.: 19/047,027

(22) Filed: Feb. 6, 2025

(51) Int. Cl. H10D 84/01; H01L 21/768; H10D 30/00; H10D 30/01; H10D 30/43; H10D 62/10; H10D 64/23; H10D 84/85

(52) U.S. Cl. CPC H10D 84/0186; H10D 30/014; H10D 30/019; H10D 30/43; H10D 30/501; H10D 62/121; H10D 64/251; H10D 84/017; H10D 84/851; H10W 20/037

(57) ABSTRACT

A method that includes forming a contact opening through a semiconductor substrate that is overlying a source/drain region. The contact opening has a non-linear profile, wherein the non-linear profile includes sidewall with a corner section. An aluminum containing dielectric layer is formed on the corner section of the sidewall of the contact opening, and a protective liner is formed on the aluminum containing dielectric layer within the contact opening. The protective liner is etched to form protective spacers, wherein the aluminum containing dielectric layer protects the semiconductor substrate from being exposed at the corner section of the sidewall of the contact opening during the etching of the protective liner. A metal semiconductor alloy is formed on the source/drain region at the base of the contact opening.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of nanostructure field-effect transistors (nano-FETs) in a three-dimensional view, in accordance with some embodiments.

FIGS. 2, 3, 4, 5, 6A, 6B, 6C, 7A, 7B, 7C, 8A, 8B, 8C, 9A, 9B, 9C, 10A, 10B, 10C, 11A, 11B, 11C, 11D, 12A, 12B, 12C, 12D, 12E, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, 22C, 23, 24, 25, 26, 27, 28, 29A, 29B and 30 are views of intermediate stages in the manufacturing of a semiconductor die including nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments described herein provide semiconductor structures with back-side interconnects, in which conformally deposited aluminum containing dielectric layers obstruct the formation of metal semiconductor alloys (such as silicide materials) on the sidewalls of a contact opening containing the back-side interconnect. The back-side interconnect may have a non-linear profile that can result from misalignment between the back-side aperture to the contact opening for containing the back-side interconnect structure and the back-side of the epitaxial material for the source/drain regions. The non-linear profile of the contact opening can include a horizontally orientated portion or slanted portion on a section of the contact opening sidewall between the aperture to the contact opening and the base of the contact opening.

In some instances, when forming dielectric liners within the contact openings during the manufacturing processes for forming the back-side interconnect, the etch processes for defining the dielectric liner can expose semiconductor material at the horizontally orientated portions or slanted portions of the sidewalls of the contact opening. The exposed semiconductor material on the sidewall of the contact opening can react with metal elements used for forming metal semiconductor alloy regions on the source/drain regions. The reaction between the exposed semiconductor material on the sidewalls of the contact opening and the metal for the metal semiconductor alloy being formed at the base of the contact opening can produce an unintended metal semiconductor alloy region on the sidewall of the interconnect.

In some embodiments, an aluminum containing dielectric liner, e.g., aluminum oxide liner, is formed on the sidewalls of the contact opening to prevent the unintended formation of the metal semiconductor alloys on the horizontally orientated portion or the slanted portion of the contact opening sidewall or maintain an acceptable distance between the metal semiconductor alloys and other features of the device (e.g., a gate stack). More particularly, the aluminum containing dielectric liner can protect the contact opening sidewalls, e.g., the horizontally orientated portions or the slanted portions of the contact opening sidewalls, from being exposed by etch processes, which prevents the formation of or maintains an acceptable spacing of the metal semiconductor alloys and the incidence of semiconductor breakage. Reducing metal semiconductor alloy formation and semiconductor breakage at the sidewalls of the back-side interconnect can reduce leakage effects, such as leakage between the back-side interconnect and adjacently positioned electrically conductive structures, such as gate structures.

Some embodiments discussed herein are described in the context of a semiconductor die including nano-FETs. However, various embodiments may be applied to dies including other types of transistors (e.g., fin field effect transistors (FinFETs), vertical field-effect transistors (VFETs), complementary field-effect transistors (CFETs), planar transistors, or the like) in lieu of or in combination with the nano-FETs.

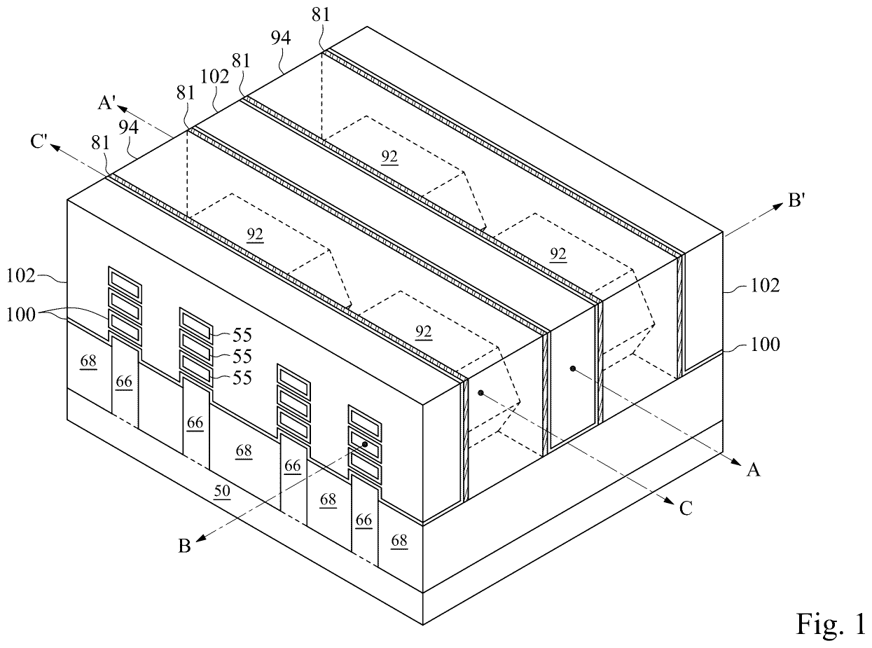

FIG. 1 illustrates an example of nano-FETs (e.g., nanowire FETs, nanosheet FETs, or the like) in a three-dimensional view. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Shallow trench isolation (STI) regions 68 are disposed between adjacent fins 66, which may protrude above and from between neighboring STI regions 68. Although the STI regions 68 are described/illustrated as being separate from the substrate 50, as used herein, the term “substrate” may refer to the semiconductor substrate alone or a combination of the semiconductor substrate and the STI regions. Additionally, although bottom portions of the fins 66 are illustrated as being single, continuous materials with the substrate 50, the bottom portions of the fins 66 and/or the substrate 50 may comprise a single material or a plurality of materials. In this context, the fins 66 refer to the portion extending between the neighboring STI regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102.

FIG. 1 further illustrates reference cross-sections that are used in later figures. Reference cross-section A-A′ is along a longitudinal axis of a gate electrode 102 and in a direction, for example, perpendicular to the direction of current flow between the epitaxial source/drain regions 92 of a nano-FET. Reference cross-section B-B′ is parallel to reference cross-section A-A′ and extends through epitaxial source/drain regions 92 of multiple nano-FETs. Reference cross-section C-C′ is perpendicular to reference cross-section A-A′ and is parallel to a longitudinal axis of a fin 66 of the nano-FET and in a direction of, for example, a current flow between the epitaxial source/drain regions 92 of the nano-FET. Reference cross-section D-D′ is parallel to reference cross-section C-C′ and extends through gate electrodes 102 of multiple nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in FinFETs.

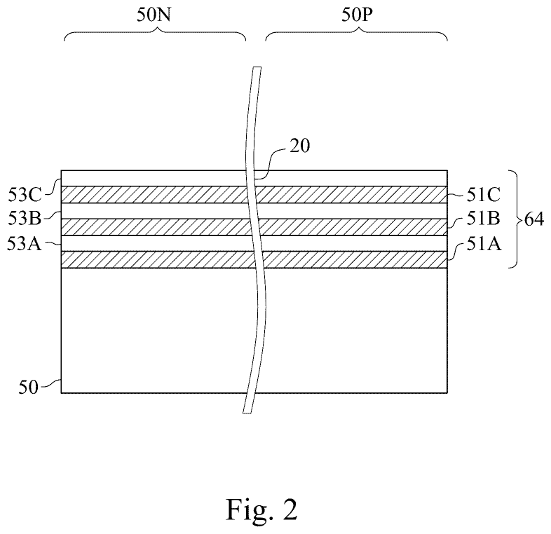

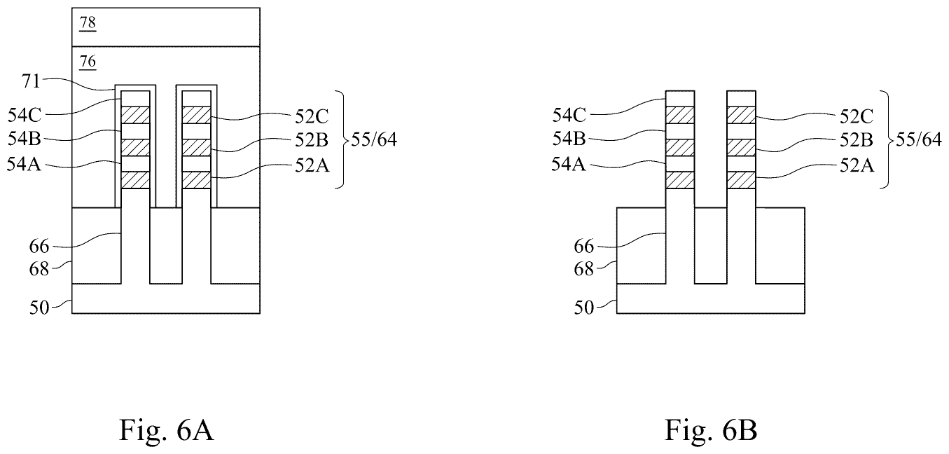

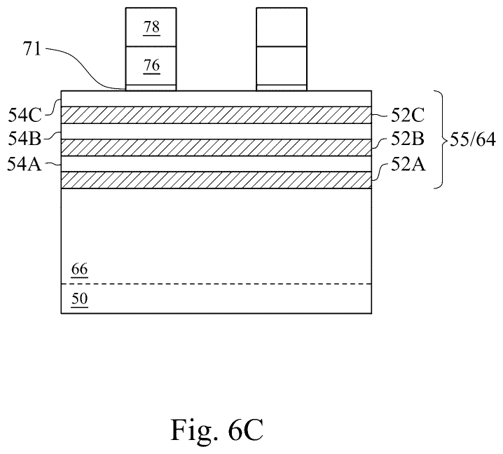

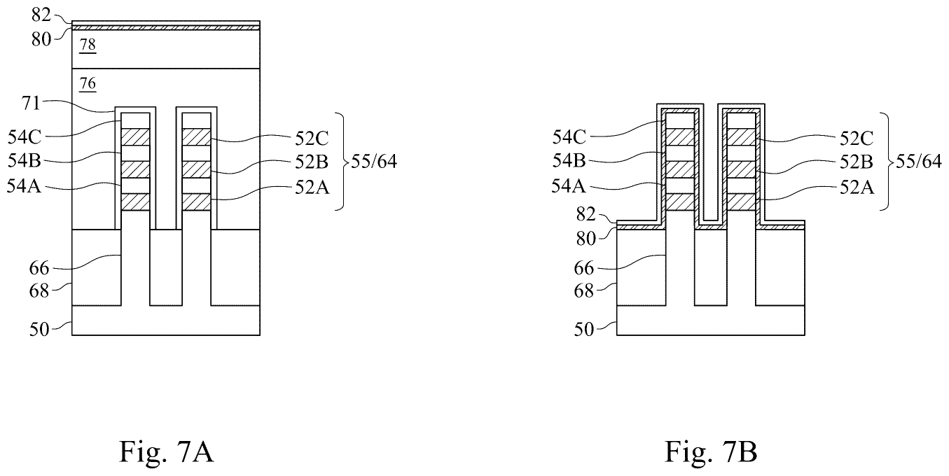

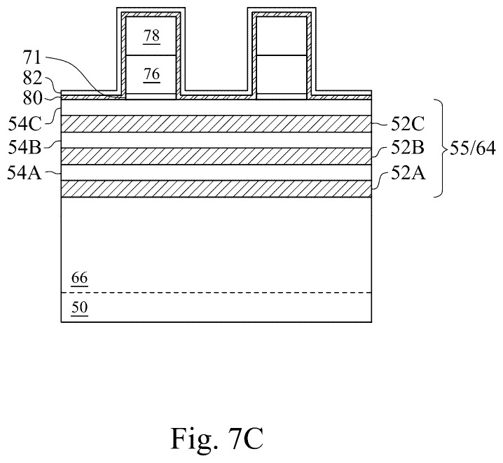

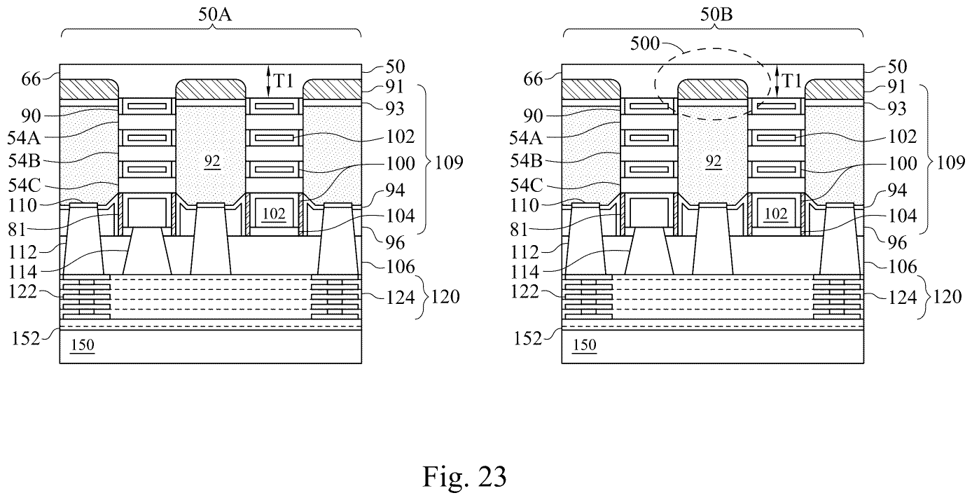

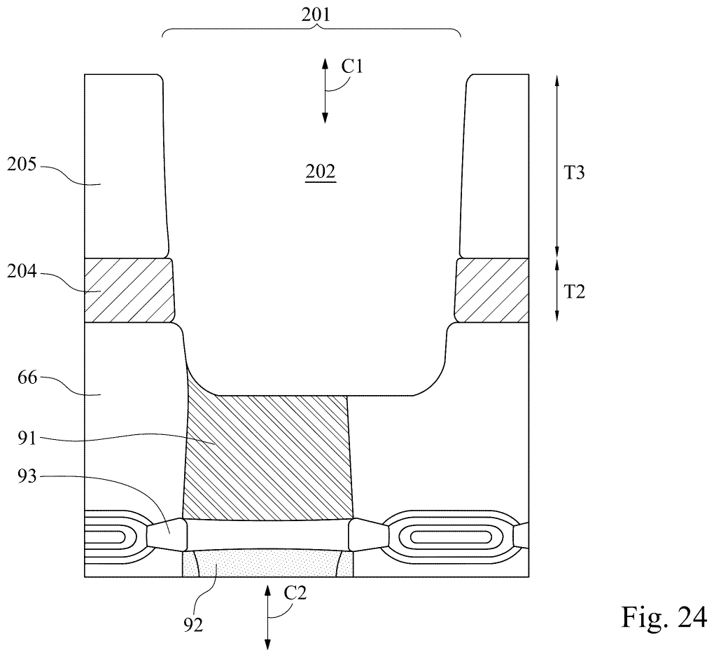

FIGS. 2 through 28C are views of intermediate stages in the manufacturing of a semiconductor die including nano-FETs, in accordance with some embodiments. FIGS. 2, 3, 4, 5, 6A, 7A, 8A, 9A, 10A, 11A, 12A, 13A, 14A, 15A, 16A, 17A, 18A, 19A, 20A, 21A, and 22A illustrate cross-sectional views along reference cross-section A-A′ illustrated in FIG. 1. FIGS. 6B, 7B, 8B, 9B, 10B, 11B, 12B, 12D, 13B, 14B, 15B, 16B, 17B, 18B, 19B, 20B, 21B, and 22B illustrate cross-sectional views along reference cross-section B-B′ illustrated in FIG. 1. FIGS. 7C, 8C, 9C, 10C, 11C, 11D, 12C, 12E, 13C, 14C, 15C, 16C, 17C, 18C, 19C, 20C, 21C, 22C, and 23 illustrate cross-sectional views along reference cross-section C-C′ illustrated in FIG. 1. FIGS. 24, 25, 26, 27, 28, 29A and 29B illustrate cross-sectional views along reference cross-section C-C′ illustrated in FIG. 1, and magnified views of the focus area (identified by reference number 500) in FIG. 23.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 has an n-type region 50N and a p-type region 50P. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). For purposes of illustration and as discussed in greater detail below, the first semiconductor layers 51 will be removed and the second semiconductor layers 53 will be patterned to form channel regions of nano-FETs in the n-type region 50N and the p-type region 50P. However, in some embodiments the first semiconductor layers 51 may be removed and the second semiconductor layers 53 may be patterned to form channel regions of nano-FETs in the n-type region 50N, and the second semiconductor layers 53 may be removed and the first semiconductor layers 51 may be patterned to form channel regions of nano-FETs in the p-type region 50P. In some embodiments the second semiconductor layers 53 may be removed and the first semiconductor layers 51 may be patterned to form channel regions of nano-FETs in the n-type region 50N, and the first semiconductor layers 51 may be removed and the second semiconductor layers 53 may be patterned to form channel regions of nano-FETs in the p-type region 50P. In some embodiments, the second semiconductor layers 53 may be removed and the first semiconductor layers 51 may be patterned to form channel regions of nano-FETs in both the n-type region 50N and the p-type region 50P.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material, such as silicon germanium or the like, and the second semiconductor layers 53 may be formed of a second semiconductor material different from the first semiconductor material, such as silicon, carbon-doped silicon, or the like.

The first semiconductor materials and the second semiconductor materials may be materials having a high etch selectivity to one another. As such, the first semiconductor layers 51 of the first semiconductor material may be removed without significantly removing the second semiconductor layers 53 of the second semiconductor material thereby allowing the second semiconductor layers 53 to be patterned to form channel regions of nano-FETs. Similarly, in embodiments in which the second semiconductor layers 53 are removed and the first semiconductor layers 51 are patterned to form channel regions, the second semiconductor layers 53 of the second semiconductor material may be removed without significantly removing the first semiconductor layers 51 of the first semiconductor material, thereby allowing the first semiconductor layers 51 to be patterned to form channel regions of nano-FETs.

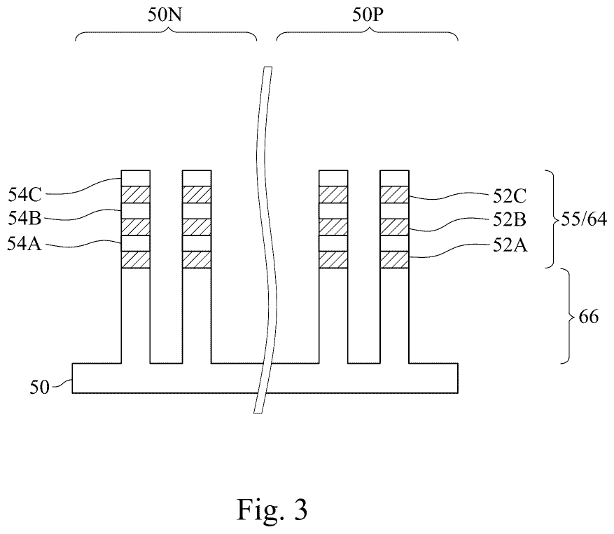

Referring now to FIG. 3, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

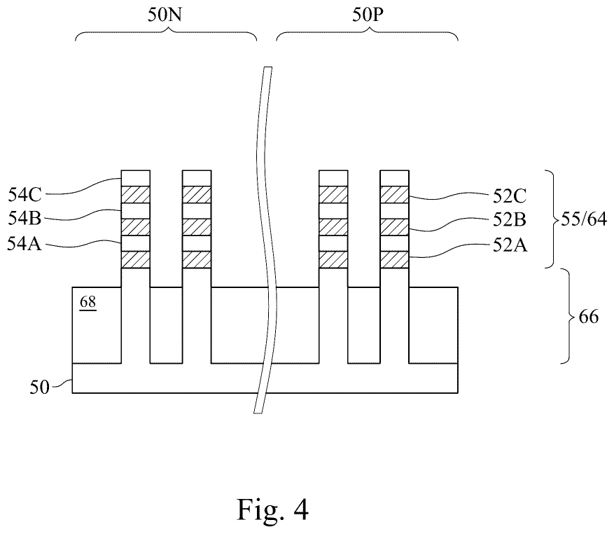

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where, epitaxial structures are epitaxially grown, the epitaxially grown materials may be in situ doped during growth, which may obviate prior and/or subsequent implantations, although in situ and implantation doping may be used together.

Additionally, the first semiconductor layers 51 (and resulting first nanostructures 52) and the second semiconductor layers 53 (and resulting second nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N.

Further in FIG. 4, appropriate wells (not separately illustrated) may be formed in the fins 66, the nanostructures 55, and/or the STI regions 68. In embodiments with different well types, different implant steps for the n-type region 50N and the p-type region 50P may be achieved using a photoresist or other masks (not separately illustrated). For example, a photoresist may be formed over the fins 66 and the STI regions 68 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other masks (not separately illustrated) is formed over the fins 66, the nanostructures 55, and the STI regions 68 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an annealing may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

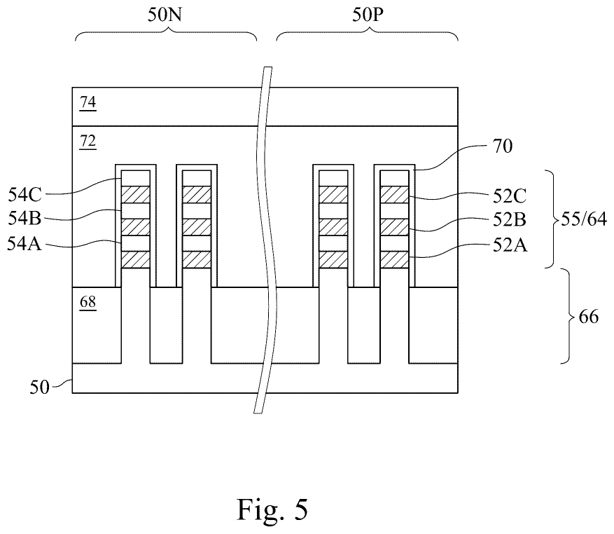

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment nano-FET devices. FIGS. 6A through 18C illustrate features in either the n-type region 50N or the p-type region 50P. In FIGS. 6A through 6C, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A through 7C, a first spacer layer 80 and a second spacer layer 82 are formed over the structures illustrated in FIGS. 6A through 6C. The first spacer layer 80 and the second spacer layer 82 will be subsequently patterned to act as spacers for forming self-aligned source/drain regions. In FIGS. 7A through 7C, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×10¹⁵ atoms/cm³ to about 1×10¹⁹ atoms/cm³. An annealing may be used to repair implant damage and to activate the implanted impurities.

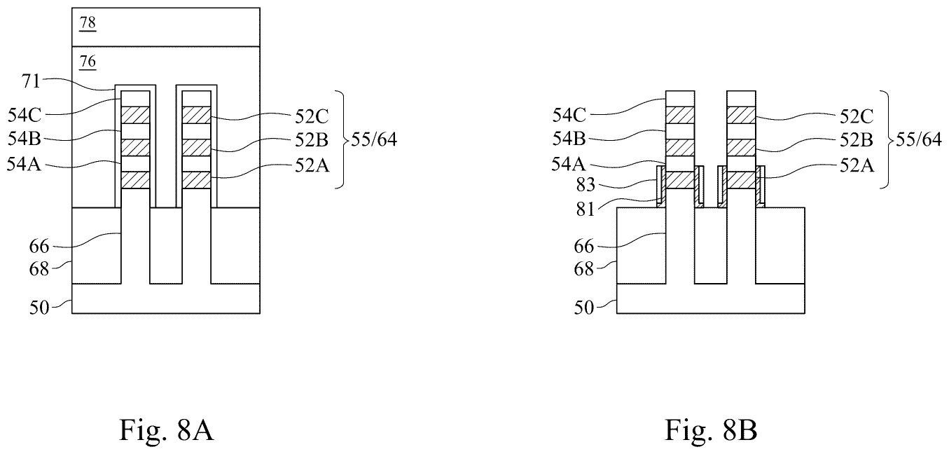

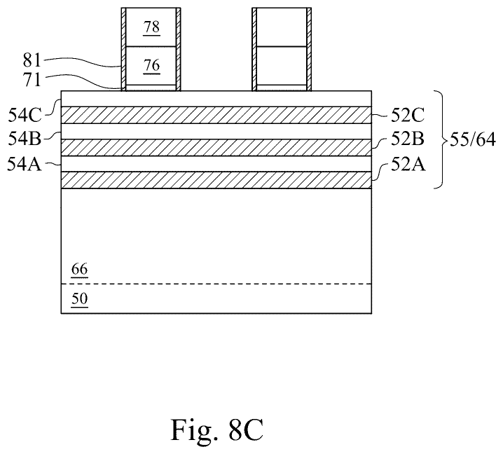

In FIGS. 8A through 8C, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8B. Thereafter, the second spacers 83 acts as a mask while etching exposed portions of the first spacer layer 80, thereby forming first spacers 81 as illustrated in FIGS. 8B and 8C.

As illustrated in FIG. 8B, the first spacers 81 and the second spacers 83 are disposed on sidewalls of the fins 66 and/or nanostructures 55. As illustrated in FIG. 8C, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

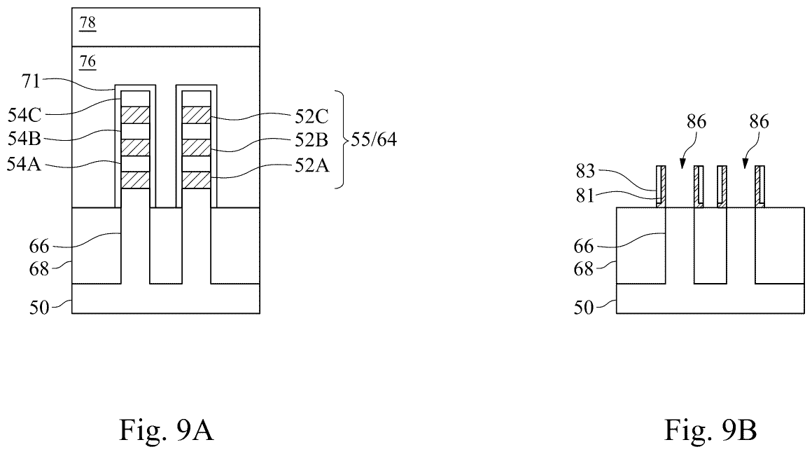

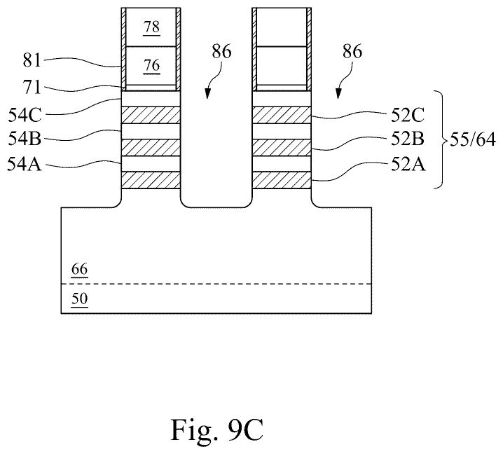

In FIGS. 9A through 9C, recesses 86 are formed in the fins 66, the nanostructures 55, and the substrate 50, in accordance with some embodiments. Epitaxial source/drain regions will be subsequently formed in the recesses 86. The recesses 86 may extend through the first nanostructures 52 and the second nanostructures 54, and into the substrate 50. As illustrated in FIG. 9B, top surfaces of the STI regions 68 may be level with bottom surfaces of the recesses 86. In various embodiments, the fins 66 may be etched such that bottom surfaces of the recesses 86 are disposed below the top surfaces of the STI regions 68 or the like. The recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the recesses 86. A single etch process or multiple etch processes may be used to etch each layer of the nanostructures 55 and/or the fins 66. Timed etch processes may be used to stop the etching after the recesses 86 reach desired depths.

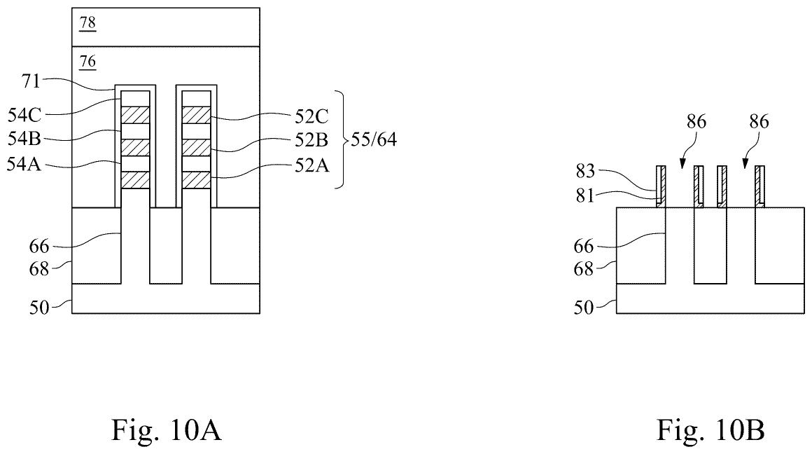

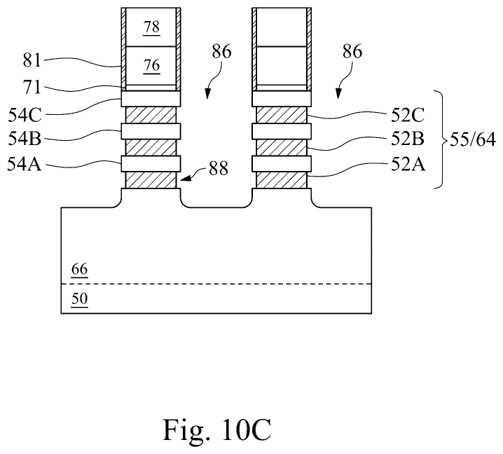

In FIGS. 10A through 10C, portions of sidewalls of the layers of the multi-layer stack 64 formed of the first semiconductor materials (e.g., the first nanostructures 52) exposed by the recesses 86 are etched to form sidewall recesses 88. Although sidewalls of the first nanostructures 52 adjacent the sidewall recesses 88 are illustrated as being straight in FIG. 10C, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH₄OH), or the like may be used to etch sidewalls of the first nanostructures 52.

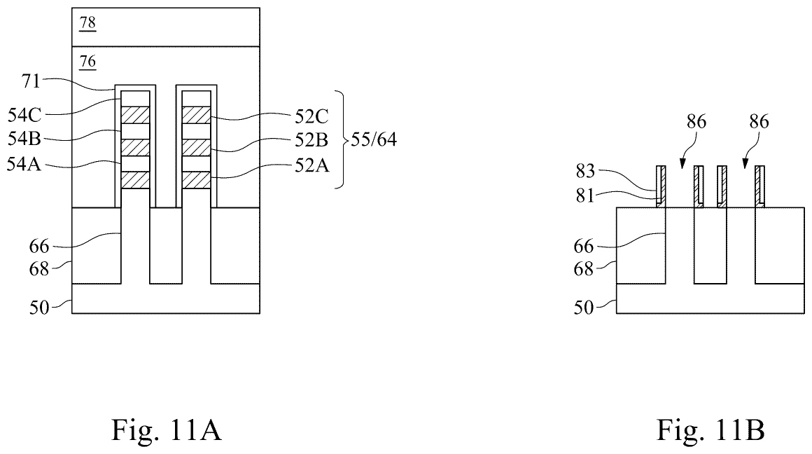

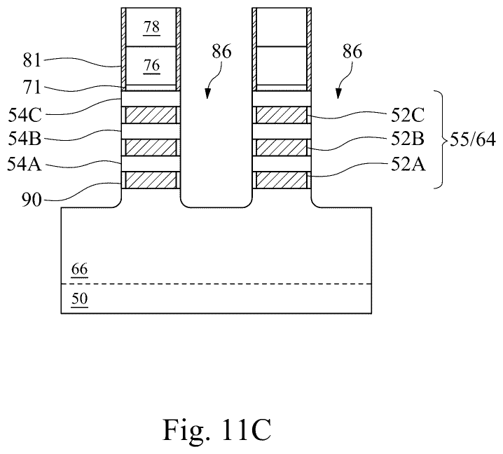

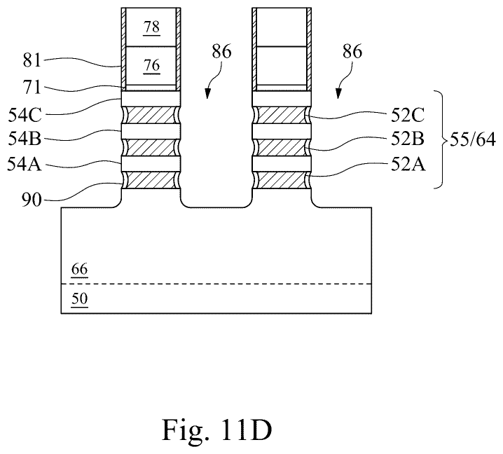

In FIGS. 11A through 11D, first inner spacers 90 are formed in the sidewall recess 88. The first inner spacers 90 may be formed by depositing an inner spacer layer (not separately illustrated) over the structures illustrated in FIGS. 10A through 10C. The first inner spacers 90 act as isolation features between subsequently formed source/drain regions and a gate structure. As will be discussed in greater detail below, source/drain regions and epitaxial materials will be formed in the recesses 86, while the first nanostructures 52 will be replaced with corresponding gate structures. The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54, the outer sidewalls of the first inner spacers 90 may extend beyond or be recessed from sidewalls of the second nanostructures 54.

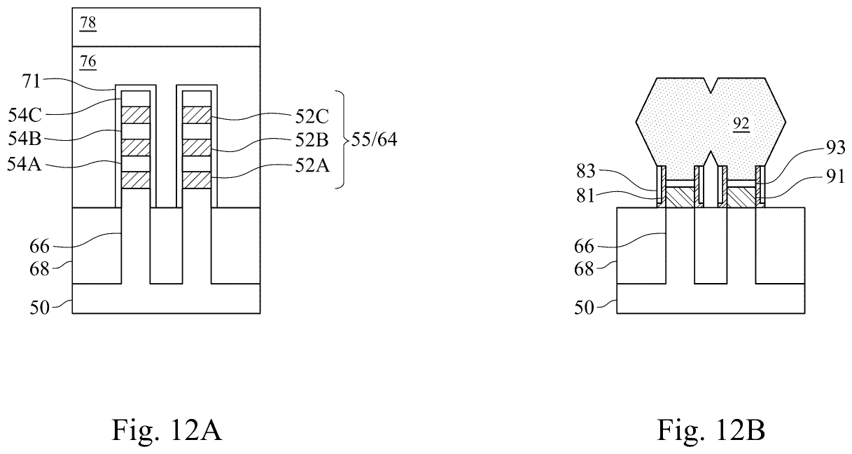

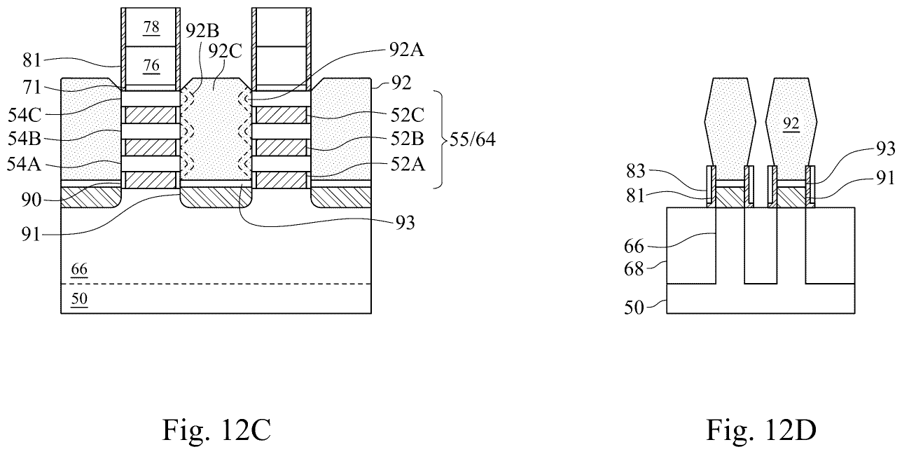

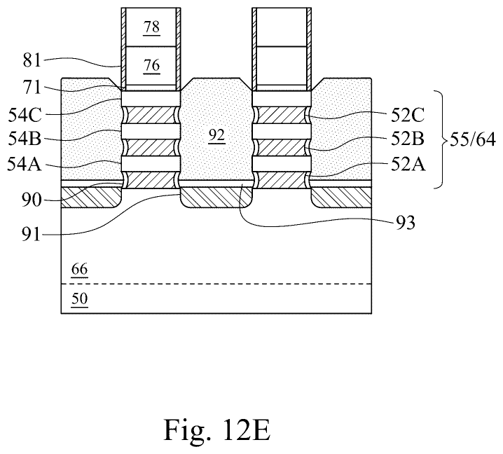

Moreover, although the outer sidewalls of the first inner spacers 90 are illustrated as being straight in FIG. 11C, the outer sidewalls of the first inner spacers 90 may be concave or convex. As an example, FIG. 11D illustrates an embodiment in which sidewalls of the first nanostructures 52 are concave, outer sidewalls of the first inner spacers 90 are concave, and the first inner spacers 90 are recessed from sidewalls of the second nanostructures 54. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A through 12E) by subsequent etching processes, such as etching processes used to form gate structures.

In FIGS. 12A through 12E, semiconductor layers 91, bottom spacers 93, and epitaxial source/drain regions 92 are formed in the recesses 86. The semiconductor layers 91 may be formed on the fins 66. The semiconductor layer 91 may be in contact with the sidewalls of the first inner spacers 90 on the first nanostructures 52A. Bottom surfaces of the semiconductor layers 91 may be disposed below bottom surfaces of the first inner spacers 90 on the first nanostructures 52A. Top surfaces of the semiconductor layers 91 may be disposed below top surfaces of the first inner spacers 90 on the first nanostructures 52A. Thus, the semiconductor layers 91 may not be on the sidewalls of the second nanostructures 54. The semiconductor layers 91 may be formed of a semiconductor material selected from the candidate semiconductor materials of the substrate 50, which may be grown by an epitaxial growth process such as VPE, MBE, or the like. For example, the semiconductor layer 91 may be composed of a germanium containing composition, such as silicon germanium (SiGe), and may be formed using an epitaxial deposition process. Timed epitaxial growth processes may be used to grow the semiconductor layers 91 to certain heights.

The bottom spacers 93 are formed on the semiconductor layers 91. The bottom spacers 93 may be in contact with the first inner spacers 90 on the first nanostructures 52A. Bottom surfaces of the bottom spacers 93 may be disposed above the bottom surfaces of the first inner spacers 90 on the first nanostructures 52A. Top surfaces of the bottom spacers 93 may be disposed below the top surfaces of the first inner spacers 90 on the first nanostructures 52A. Thus, the bottom spacers 93 may not be on the sidewalls of the second nanostructures 54. The bottom spacers 93 may be formed by conformally forming one or more dielectric material(s) over the semiconductor layers 91 and subsequently etching back the dielectric material(s). Acceptable dielectric materials may include silicon nitride, silicon oxynitride, silicon oxycarbonitride, silicon oxycarbide, silicon carbonitride, silicon oxide, aluminum oxide, hafnium oxide, or the like, which may be formed by a deposition process, such as CVD, ALD, or the like. Any acceptable etch process, such as a dry etch, a wet etch, the like, or a combination thereof, may be performed to pattern the dielectric material(s). In some embodiments, the bottom spacers 93 may be composed of a boron doped nitride.

In some embodiments, the bottom spacers 93 may be formed before forming the epitaxial source/drain regions 92. In some embodiments, the bottom spacers 93 provides for greater insulation around the epitaxial source/drain regions 92 and may reduce leakage effects. The bottom spacers 93 may also be referred to as an isolation layer, a bottom isolation layer, or a flexible bottom isolation (FBI) layer. The bottom spacers 93 may also be referred to as a floating bottom isolation layer.

The epitaxial source/drain regions 92 are then formed in the recesses 86 and on the bottom spacers 93. In some embodiments, the epitaxial source/drain regions 92 may exert stress on the second nanostructures 54, thereby improving performance. As illustrated in FIG. 12C, the epitaxial source/drain regions 92 are formed in the recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the recesses 86 in the n-type region 50N. The epitaxial source/drain regions 92 may include any acceptable material appropriate for n-type nano-FETs. For example, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the recesses 86 in the p-type region 50P. The epitaxial source/drain regions 92 may include any acceptable material appropriate for p-type nano-FETs. For example, if the first nanostructures 52 are silicon germanium, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 64 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12B. In other embodiments, adjacent epitaxial source/drain regions 92 remain separated after the epitaxy process is completed as illustrated by FIG. 12D. In the embodiments illustrated in FIGS. 12B and 12D, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 58.

The epitaxial source/drain regions 92 may comprise one or more semiconductor material layers. In some embodiments, the epitaxial source/drain regions 92 comprise first liner layers 92A on the sidewalls of the second nanostructures 54, second liner layers 92B on the first liner layers 92A, and fill layers 92C on the second liner layers 92B, as shown in FIG. 12C. The first liner layers 92A, the second liner layers 92B, and the fill layers 92C may be formed of different semiconductor materials and/or may be doped to different dopant concentrations. The first liner layers 92A may be grown first, the second liner layers 92B may be grown on the first liner layers 92A, and the fill layers 92C may be grown on the second liner layers 92B.

FIG. 12E illustrates an embodiment in which sidewalls of the first nanostructures 52 are concave, outer sidewalls of the first inner spacers 90 are concave, and the first inner spacers 90 are recessed from sidewalls of the second nanostructures 54. As illustrated in FIG. 12E, the epitaxial source/drain regions 92 may be formed in contact with the first inner spacers 90 and may extend past sidewalls of the second nanostructures 54.

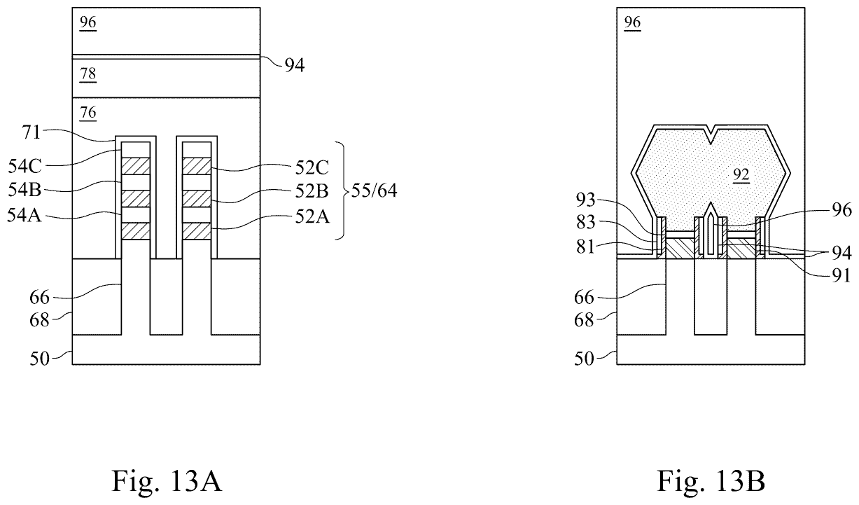

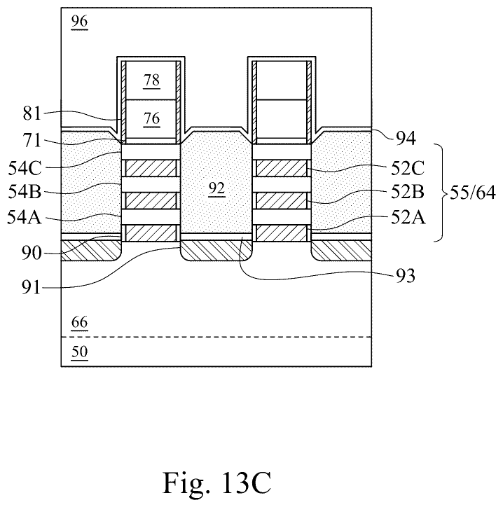

In FIGS. 13A through 13C, a first interlayer dielectric (ILD) 96 is deposited over the structure illustrated in FIGS. 12A through 12C. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

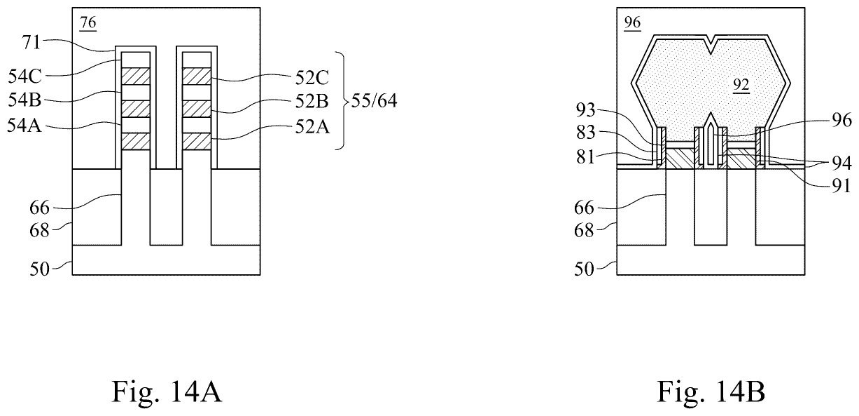

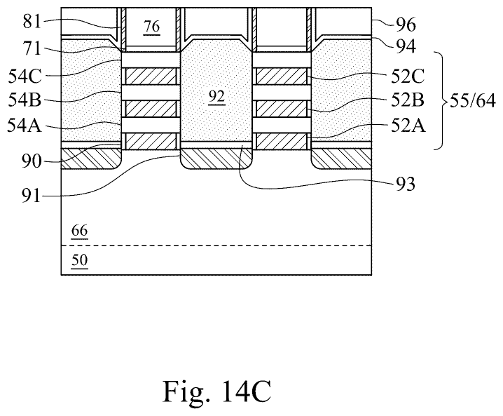

In FIGS. 14A through 14C, a planarization process, such as CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

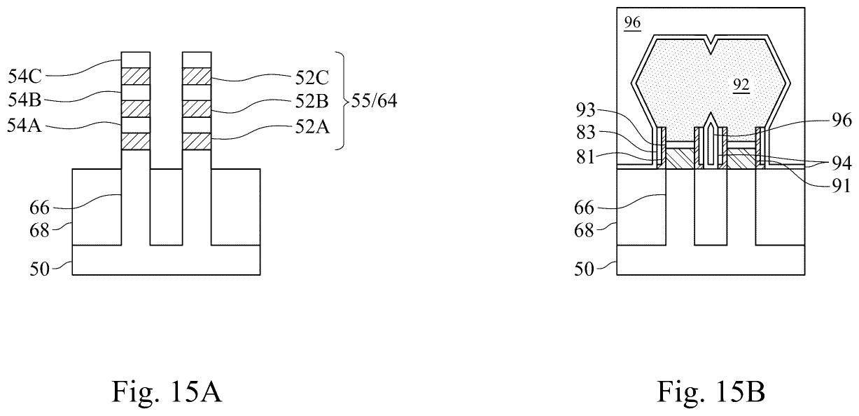

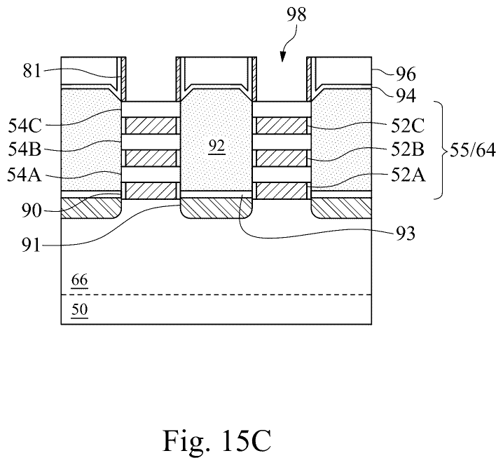

In FIGS. 15A through 15C, the dummy gates 76, and the masks 78 if present, are removed in one or more etching steps, so that third recesses 98 are formed. Portions of the dummy gate dielectrics 71 in the third recesses 98 are also be removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96 or the first spacers 81. Each of the third recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

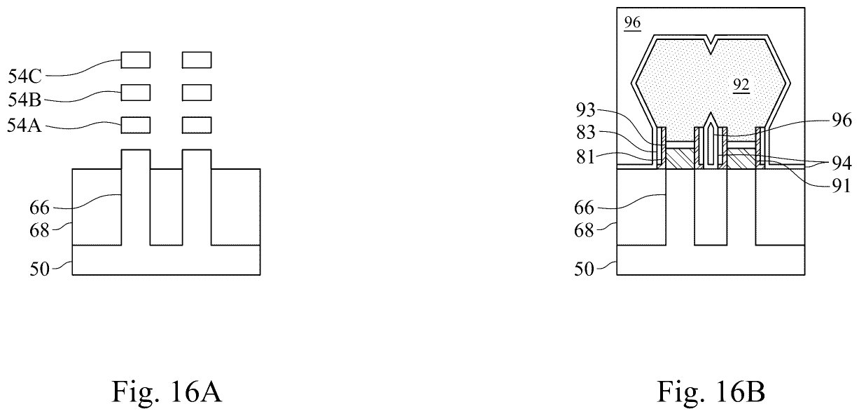

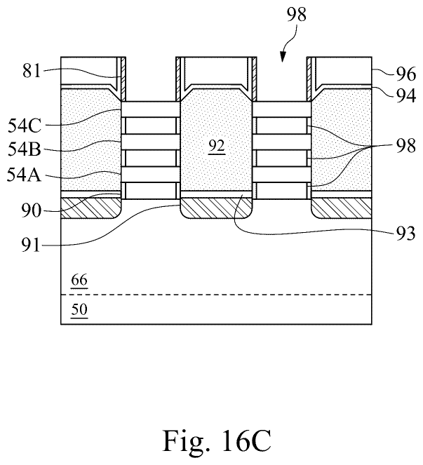

In FIGS. 16A through 16C, the first nanostructures 52 are removed extending the third recesses 98. The first nanostructures 52 may be removed by performing an isotropic etching process such as wet etching or the like using etchants which are selective to the materials of the first nanostructures 52, while the second nanostructures 54, the substrate 50, the STI regions 68 remain relatively unetched as compared to the first nanostructures 52. In embodiments in which the first nanostructures 52 include, e.g., SiGe, and the second nanostructures 54A-54C include, e.g., Si or SiC, tetramethylammonium hydroxide (TMAH), ammonium hydroxide (NH₄OH), or the like may be used to remove the first nanostructures 52.

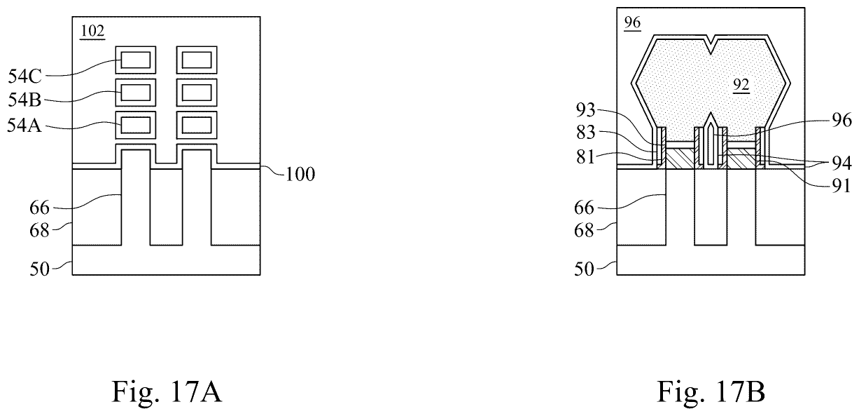

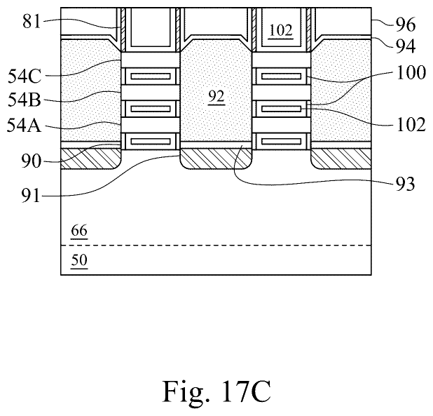

In FIGS. 17A through 17C, gate dielectric layers 100 and gate electrodes 102 are formed for replacement gates. The gate dielectric layers 100 are deposited conformally in the third recesses 98. The gate dielectric layers 100 may be formed on top surfaces and sidewalls of the substrate 50 and on top surfaces, sidewalls, and bottom surfaces of the second nanostructures 54. The gate dielectric layers 100 may also be deposited on top surfaces of the first ILD 96, the CESL 94, the first spacers 81, and the STI regions 68 and on sidewalls of the first spacers 81 and the first inner spacers 90.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a dielectric constant (k) value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the third recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17C, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54 and between the second nanostructure 54A and the substrate 50, and may be deposited in the p-type region 50P between adjacent ones of the first nanostructures 52.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the third recesses 98, a planarization process, such as CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

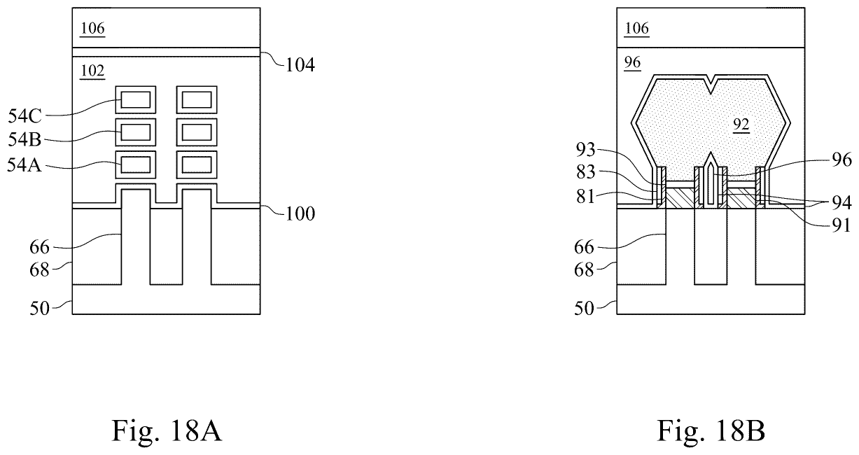

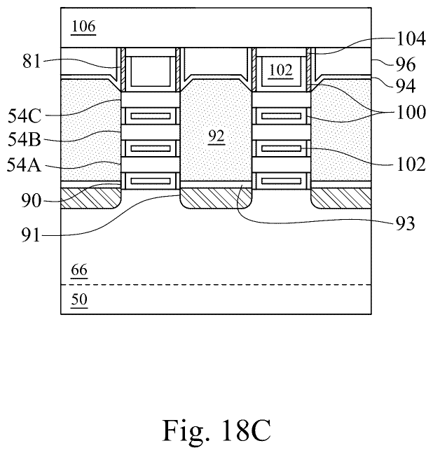

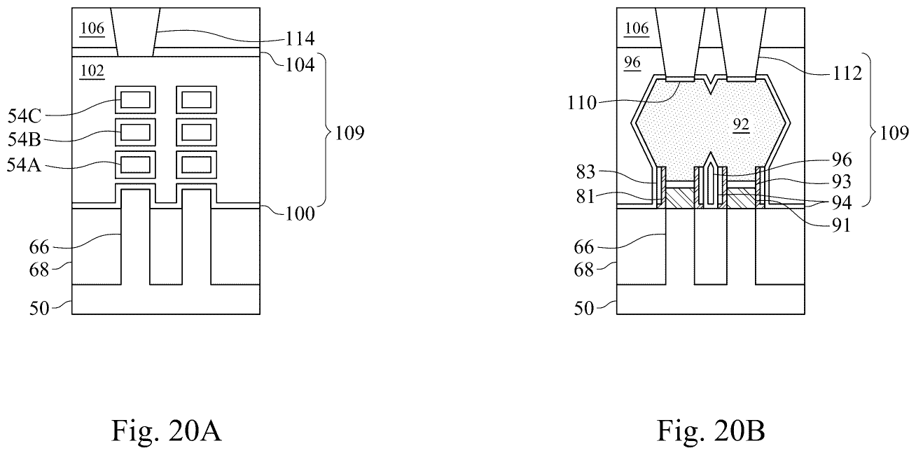

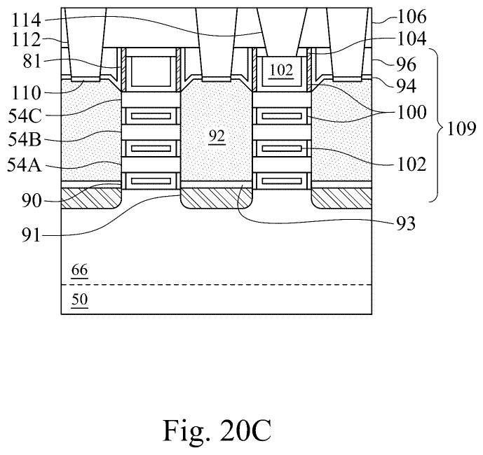

In FIGS. 18A through 18C, the gate structures (including the gate dielectric layers 100 and the corresponding overlying gate electrodes 102) are recessed, so that recess are formed directly over the gate structures and between opposing portions of first spacers 81. Gate masks 104 comprising one or more layers of dielectric material, such as silicon nitride, silicon oxynitride, or the like, are filled in the recesses, followed by a planarization process to remove excess portions of the dielectric material extending over the first ILD 96. Subsequently formed gate contacts (such as the gate contacts 114, discussed below with respect to FIGS. 20A through 20C) penetrate through the gate masks 104 to contact the top surfaces of the recessed gate electrodes 102.

As further illustrated by FIGS. 18A through 18C, a second ILD 106 is deposited over the first ILD 96 and over the gate masks 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

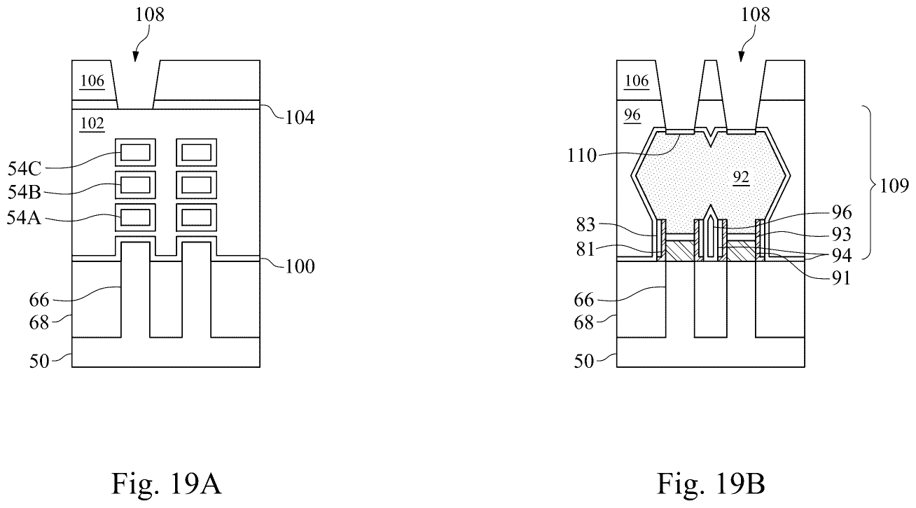

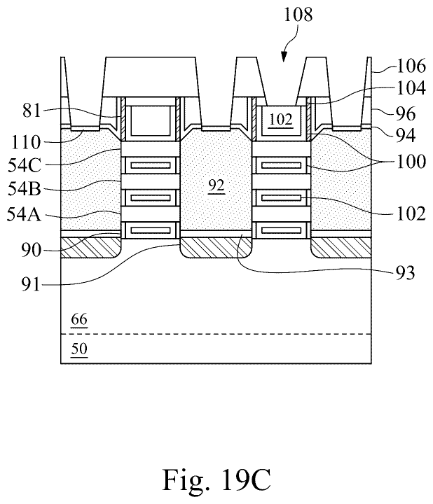

In FIGS. 19A through 19C, the second ILD 106, the first ILD 96, the CESL 94, and the gate masks 104 are etched to form fourth recesses 108 exposing surfaces of the epitaxial source/drain regions 92 and/or some of the gate structures. Some of the gate structures may not be exposed by the fourth recesses 108. Desired one of the gate structures (e.g., ones that are not exposed by the fourth recesses 108) may be connected to conductive contacts that extend through the substrate 50, which may be subsequently formed as described in greater detail below. The fourth recesses 108 may be formed by etching using an anisotropic etching process, such as RIE, NBE, or the like. In some embodiments, the fourth recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the fourth recesses 108 extend into the epitaxial source/drain regions 92 and/or some of the gate structures, and a bottom of the fourth recesses 108 may be level with (e.g., at a same level, or having a same distance from the substrate 50), or lower than (e.g., closer to the substrate 50) the epitaxial source/drain regions 92 and/or some of the gate structures. Although FIG. 19C illustrates the fourth recesses 108 as exposing the epitaxial source/drain regions 92 and some of the gate structures in a same cross-section, in various embodiments, the epitaxial source/drain regions 92 and some of the gate structures may be exposed in different cross-sections, thereby reducing the risk of shorting subsequently formed contacts.

After the fourth recesses 108 are formed, first silicide regions 110 are formed over the epitaxial source/drain regions 92. In some embodiments, the first silicide regions 110 are formed by first depositing a metal (not separately illustrated) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a first thermal annealing process to form the first silicide regions 110. In some embodiments, the first thermal annealing process is performed at a temperate of about 450° C. The un-reacted portions of the deposited metal are then removed, e.g., by an etching process. Although the first silicide regions 110 are referred to as silicide regions, the first silicide regions 110 may also be germanide regions, or silicon germanide regions (e.g., regions comprising silicide and germanide).

In FIGS. 20A through 20C, source/drain contacts 112 and gate contacts 114, which may be also referred to as conductive contacts, are formed in the fourth recesses 108. The source/drain contacts 112 and the gate contacts 114 may each comprise one or more layers, such as barrier layers, diffusion layers, and fill materials. For example, in some embodiments, the source/drain contacts 112 and the gate contacts 114 each include a barrier layer and a conductive material, and are each electrically connected to an underlying conductive feature (e.g., a gate electrode 102 and/or a first silicide region 110). The gate contacts 114 are electrically connected to the gate electrodes 102 and the source/drain contacts 112 are electrically connected to the first silicide regions 110. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as CMP, may be performed to remove excess material from surfaces of the second ILD 106.

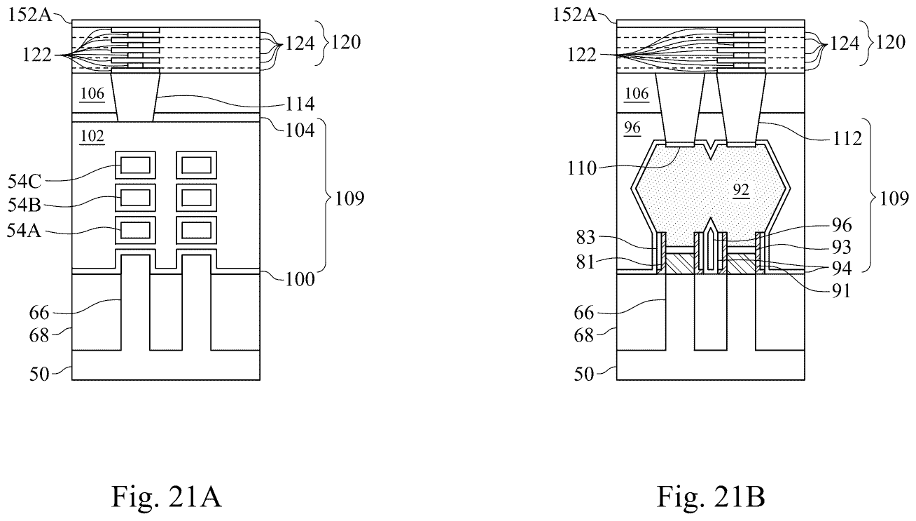

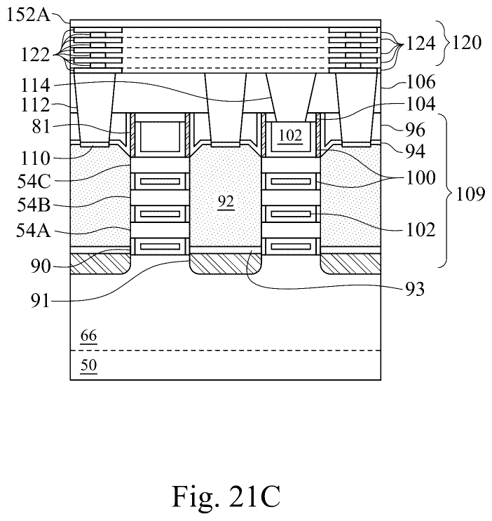

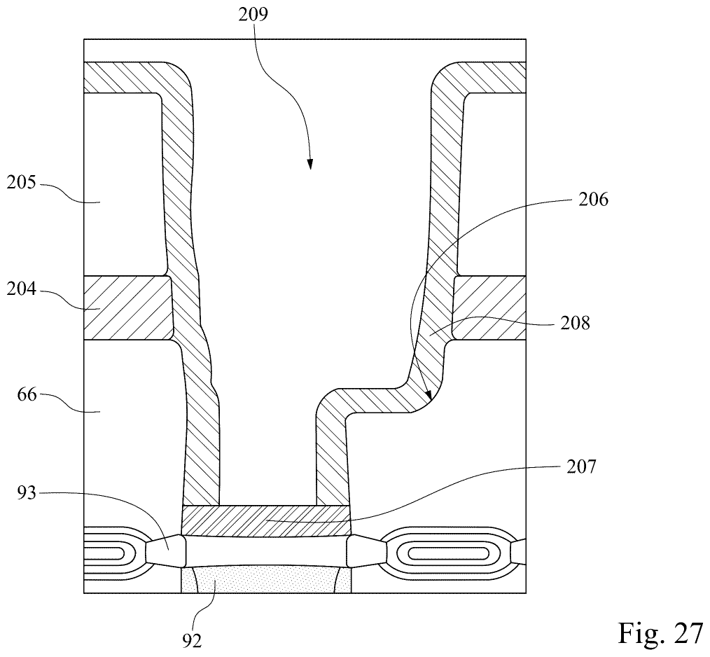

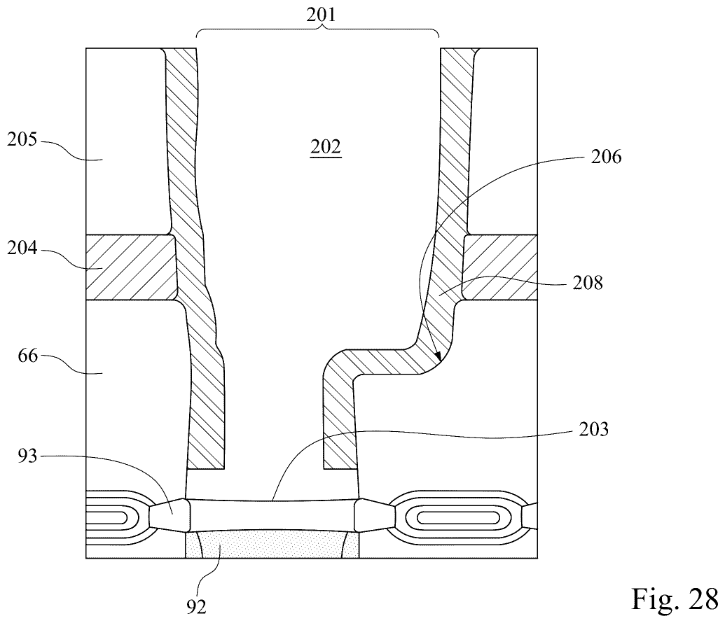

The epitaxial source/drain regions 92, the second nanostructures 54 (e.g., channel regions), and the gate structures (including the gate dielectric layers 100 and the gate electrodes 102) may collectively be referred to as transistor structures 109. The transistor structures 109 may be collectively disposed in a device layer, with a first interconnect structure (such as the front-side interconnect structure 120, discussed below with respect to FIGS. 21A through 21C) being formed over a front-side of the device layer, and a second interconnect structure (such as the back-side interconnect structure 136, discussed below with respect to FIGS. 27A through 28C) being formed over a back-side of the device layer. Although the device layer is described as having nano-FETs, other embodiments may include a device layer having different types of transistors (e.g., planar FETs, finFETs, thin film transistors (TFTs), or the like).

FIGS. 20A through 20C illustrate some of the gate structures not being connected to the gate contacts 114. As described in greater detail below, some gate structures (e.g., the gate structures that are not connected to the conductive contacts on the front-sides of the transistor structures 109) may be connected to conductive contacts that will be subsequently formed on the back-sides of the transistor structures 109. As a result, the density of the conductive contacts, including the source/drain contacts 112 and the gate contacts 114, on the front-sides of the transistor structures 109 may be reduced, which may reduce shorting and parasitic capacitance between adjacent conductive contacts on the front-sides of the transistor structures 109, thereby improving the performance and the long-term reliability of the semiconductor die.

FIGS. 20A through 20C illustrate a source/drain contact 112 extending to each of the epitaxial source/drain regions 92 on the front-sides of the transistor structures 109 as an example. In some embodiments, as described in greater detail below, conductive contacts may be subsequently formed on the back-sides of the transistor structures 109 to be electrically connected to the back-sides of some of the epitaxial source/drain regions 92. For such epitaxial source/drain regions 92, the source/drain contacts 112 at the front-sides of the epitaxial source/drain regions 92 may be omitted.

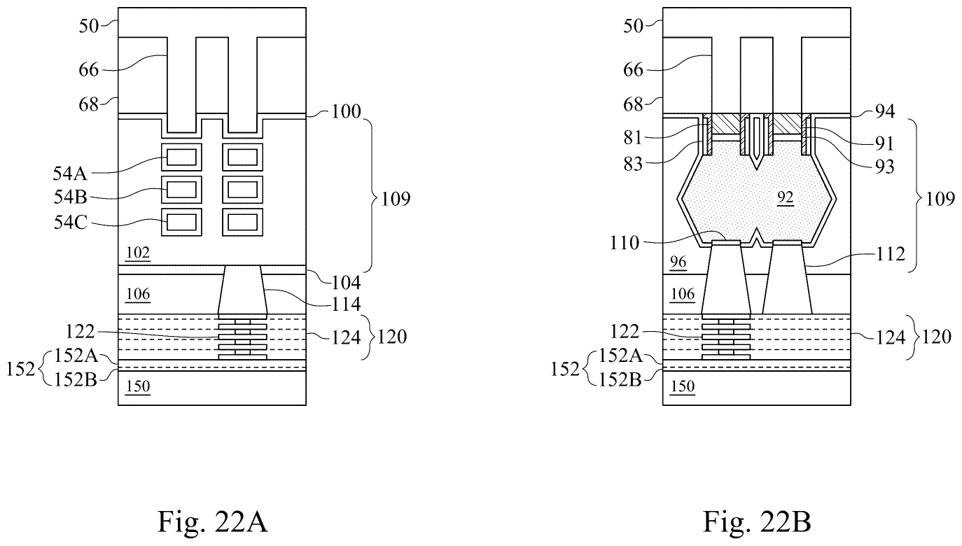

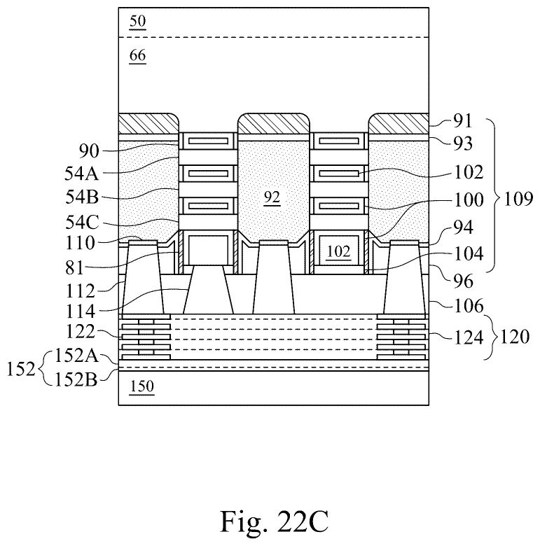

FIGS. 21A through 22B illustrate intermediate stages of forming front-side interconnect structures on the transistor structures 109. The front-side interconnect structures comprise conductive features that are electrically connected to the nano-FETs formed on the substrate 50 to provide functional circuits. The processes described in FIGS. 21A through 22B may be applied to both the n-type region 50N and the p-type region 50P.

In FIGS. 21A through 21C, a front-side interconnect structure 120 is formed on the second ILD 106. The front-side interconnect structure 120 may be referred to as a front-side interconnect structure because it is formed on the front-sides of the transistor structures 109 (e.g., a side of the transistor structures 109 on which active devices are formed). The front-side interconnect structure 120 may comprise one or more layers of first conductive features 122 formed in one or more stacked first dielectric layers 124. Each of the stacked first dielectric layers 124 may comprise a dielectric material, such as a low-k dielectric material, an extra low-k (ELK) dielectric material, or the like. The first dielectric layers 124 may be deposited using an appropriate process, such as, CVD, ALD, PVD, PECVD, or the like. The first conductive features 122 may comprise conductive lines and conductive vias interconnecting the layers of conductive lines. The conductive vias may extend through respective ones of the first dielectric layers 124 to provide vertical connections between layers of the conductive lines. A first layer of the conductive lines may be in contact with the source/drain contacts 112 and the gate contacts 114. The first conductive features 122 may be formed through any acceptable process, such as, a damascene process, a dual damascene process, or the like.

In some embodiments, the first conductive features 122 may be formed using a damascene process in which a respective first dielectric layer 124 is patterned utilizing a combination of photolithography and etching techniques to form trenches corresponding to the desired pattern of the first conductive features 122. An optional diffusion barrier and/or optional adhesion layer may be deposited, and the trenches may then be filled with a conductive material. Suitable materials for the barrier layer include titanium, titanium nitride, titanium oxide, tantalum, tantalum nitride, titanium oxide, combinations thereof, or the like, and suitable materials for the conductive material include copper, silver, gold, tungsten, aluminum, combinations thereof, or the like. In an embodiment, the first conductive features 122 may be formed by depositing a seed layer of copper or a copper alloy, and filling the trenches by electroplating. A chemical mechanical planarization (CMP) process or the like may be used to remove excess conductive material from a surface of the respective first dielectric layer 124 and to planarize surfaces of the first dielectric layer 124 and the first conductive features 122 for subsequent processing.

FIGS. 21A through 21C illustrate five layers of the first conductive features 122 and the first dielectric layers 124 in the front-side interconnect structure 120. However, it should be appreciated that the front-side interconnect structure 120 may comprise any number of first conductive features 122 disposed in any number of first dielectric layers 124. The front-side interconnect structure 120 may be electrically connected to the gate contacts 114 and the source/drain contacts 112 to form functional circuits. In some embodiments, the functional circuits formed by the front-side interconnect structure 120 may comprise logic circuits, memory circuits, image sensor circuits, or the like.

As also illustrated in FIGS. 21A through 21C, a first bonding layer 152A may be deposited over the front-side interconnect structure 120. The first bonding layer 152A may be deposited by any suitable process, such as PVD, CVD, ALD, or the like, and the first bonding layer 152A may facilitate the bonding of a carrier substrate in subsequent processes (see FIGS. 22A through 22C). The first bonding layer 152A may comprise an insulating material that is suitable for a subsequent dielectric-to-dielectric bonding process. Example materials for the first bonding layer 152A include silicon oxide (e.g., SiO₂), silicon nitride, silicon oxynitride, silicon carbonitride, silicon oxycarbonitride, or the like. Then a planarization process, such as CMP or the like, may be used to remove excess material from a surface of the first bonding layer 152A and to planarize the surface of the first bonding layer 152A for subsequent processing.

In FIGS. 22A through 22C, a carrier substrate 150 is bonded to a top surface of the front-side interconnect structure 120 by the first bonding layer 152A and a second bonding layer 152B. After bonding, the first bonding layer 152A and the second bonding layer 152B may be collectively referred to as a bonding layer 152. It should be appreciated that the bonding layer 152 may include an internal interface where the first bonding layer 152A and the second bonding layer 152B meet. The carrier substrate 150 may be a glass carrier substrate, a ceramic carrier substrate, a wafer (e.g., a silicon wafer), or the like. The carrier substrate 150 may provide structural support during subsequent processing steps and in the completed device. The second bonding layer 152B may be deposited on the carrier substrate 150 by any suitable process, such as PVD, CVD, ALD, or the like. The second bonding layer 152B may comprise an insulating material that is suitable for a dielectric-to-dielectric bonding process. Example materials for the second bonding layer 152B include silicon oxide (e.g., SiO₂), silicon nitride, silicon oxynitride, silicon carbonitride, silicon oxycarbonitride, or the like. The second bonding layer 152B may have a same or different thickness than the first bonding layer 152A.

After the second bonding layer 152B is deposited on the carrier substrate 150, the carrier substrate 150 may be bonded to the front-side interconnect structure 120 using a suitable technique, such as dielectric-to-dielectric bonding, or the like. The dielectric-to-dielectric bonding process may include applying a surface treatment to one or more of the first bonding layer 152A and the second bonding layer 152B. The surface treatment may include a plasma treatment. The plasma treatment may be performed in a vacuum environment. After the plasma treatment, the surface treatment may further include a cleaning process (e.g., a rinse with deionized water or the like) that may be applied to one or more of the bonding layers 152. The carrier substrate 150 is then aligned with the front-side interconnect structure 120 and the two are pressed against each other to initiate a pre-bonding of the carrier substrate 150 to the front-side interconnect structure 120. The pre-bonding may be performed at room temperature (e.g., between about 21° C. and about 25° C.). After the pre-bonding, an annealing process may be applied by, for example, heating the front-side interconnect structure 120 and the carrier substrate 150 to a temperature of in a range of 150° C. to 500° C. The annealing process drives the formation of covalent bonds between the first bonding layer 152A and the second bonding layer 152B. Other bonding processes, such as ambient bonding, vacuum bonding, or the like may be used in other embodiments.

Further in FIGS. 22A through 22C, after the carrier substrate 150 is bonded to the front-side interconnect structure 120, the device may be flipped such that a back-side of the transistor structures 109 faces upwards. The back-side of the transistor structures 109 may refer to a side opposite to the front-sides of the transistor structures 109 on which the active devices are formed.

FIG. 23 illustrates additional steps in the manufacturing of the semiconductor die. A region 50A and a region 50B of the semiconductor die are illustrated. The region 50A and the region 50B may be along a same fin 66 or along different fins 66. The region 50A and the region 50B may be across a same gate electrode 102 or across different gate electrodes 102.

In FIG. 23, a thinning process may be applied to the back-side of the substrate 50 in the region 50A and the region 50B. The thinning process may comprise a planarization process (e.g., a mechanical grinding, a CMP, or the like), an etch-back process, a combination thereof, or the like. Further, a portion of the substrate 50 may remain over the gate structures (e.g., the gate electrodes 102 and the gate dielectric layers 100), the semiconductor layers 91, and the bottom spacers 93. After the thinning process, the substrate 50 may have a thickness T1, which may be a distance between a surface of the gate structure (e.g., the gate electrodes 102 and the gate dielectric layers 100) and a back-side surface of the substrate 50. The thickness T1 may be in a range of about 5 nm to about 50 nm.

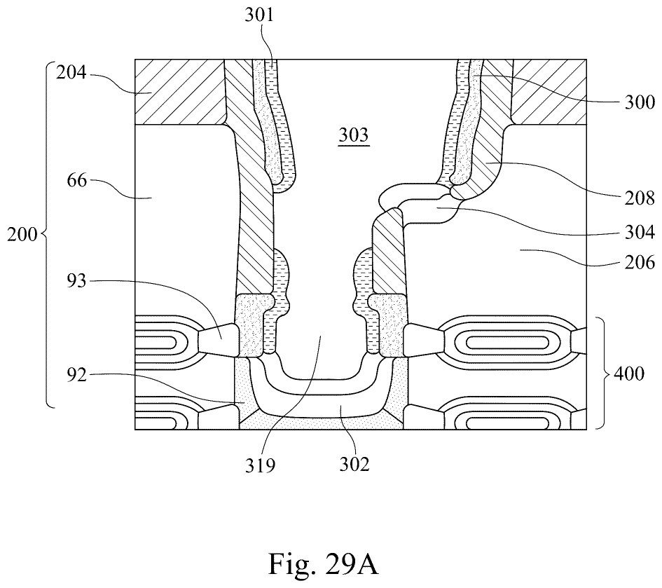

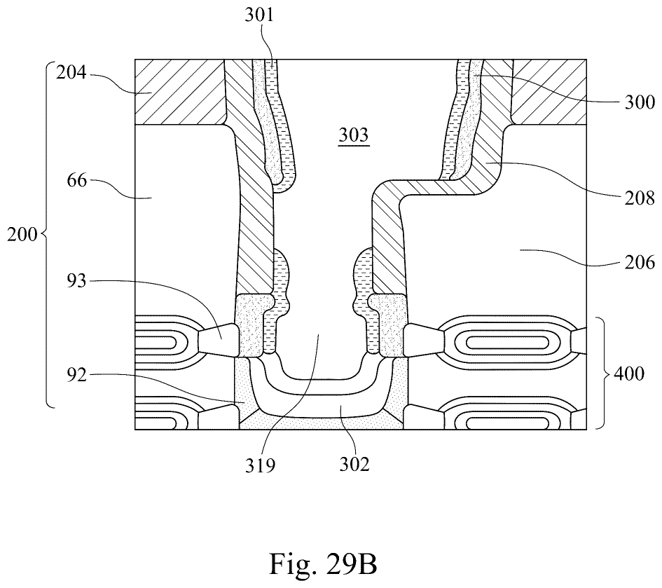

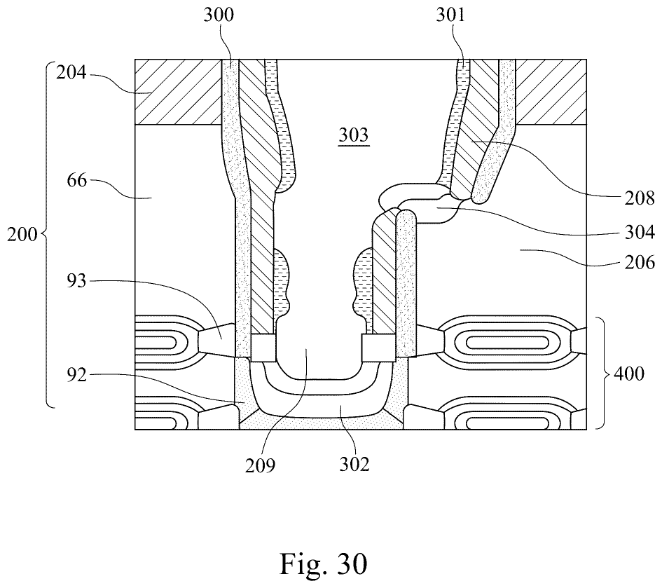

FIGS. 24-30 illustrate some embodiments of forming a back-side interconnect 200 (final structure depicted in FIGS. 29A, 29B and 30, also referred to as a back-side source/drain contact 200) having a non-linear profile. For example, the non-linear profile may include the center of the back-side contact aperture 201 to the contact opening 202 containing the back-side interconnect 200 is laterally offset from the center of the epitaxial source/drain region 92 that the back-side interconnect 200 is in electrical communication with. FIGS. 24-30 illustrate magnified views of the focus area identified by reference number 500 in FIG. 23. The back-side interconnect 200 includes conductive features that are electrically connected to the epitaxial source/drain regions 92 of the nano-FETs to provide functional circuits. The processes described in FIGS. 24 through 30 may be applied to both the n-type region 50N and the p-type region 50P.

In FIG. 24, a first back-side dielectric layer 204 is formed on the back-side surface of the substrate (portion of the substrate that provides the fin 66), and a second back-side dielectric layer 205 is formed on first back-side dielectric layer 204. The second back-side dielectric layer 205 may be used as hard masks in a subsequent etching process, and may be formed of different materials. The first back-side dielectric layer 204 may be formed of a first dielectric material (e.g., silicon nitride or the like) and the second back-side dielectric layer 205 may be formed of a second dielectric material (e.g., silicon oxide or the like). The first back-side dielectric layer 204 and the second back-side dielectric layer 205 may be formed by multiple deposition processes, such as CVD, ALD, or the like. The first back-side dielectric layer 204 may have thickness T2 in a range of about 5 nm to about 15 nm. The second back-side dielectric layer 205 may have thickness T3 in a range of about 15 nm to about 45 nm.

In FIG. 24, a mask structure is formed on the second back-side dielectric layer 205 that is patterned to defined a contact aperture 201. For example, a photoresist layer may be deposited, patterned and developed on the second back-side dielectric layer 205. The second back-side dielectric layer 205 may then be etched, e.g., using an anisotropic etch, such as reactive ion etch, using the patterned photoresist layer as a mask. The etched second back-side dielectric layer 205 may then be utilized as a hard mask to etch the first back-side dielectric layer 204 and the back-side surface of the substrate (e.g., portion of the substrate that provides the fin 66) forming the contact aperture 201 to a first portion of the contact opening 202. In some embodiments, the back-side surface of the substrate (portion of the substrate the provides the fin 66) may be etched by a dry etching process utilizing etchants such as chlorine, hydrobromic acid, oxygen, combinations thereof, or the like.

In some embodiments, the first portion of the contact opening 202 may expose a back-side surface of the semiconductor layer 91. In some embodiments, the first portion of the contact opening 202 may be etched by an anisotropic etch, such as reactive ion etching (RIE). In some embodiments, the first portion of the contact opening 202 may be etched into the back-side surface of the substrate (portion of the substrate that provides the fin 66) with an etch that is selective to the semiconductor layer 91. For example, when the back-side surface of the substrate (portion of the substrate that provides the fin 66) is composed of silicon, the etch chemistry for forming the first portion of the contact opening 202 may be selective to a semiconductor layer 91 that is composed of a germanium containing composition, such as silicon germanium.

FIG. 24 illustrates misalignment of the mask for patterning the hardmask for defining the contact aperture 201 to the back-side of the epitaxial material for the source/drain regions 92. For example, the center C1 of the width for the contact aperture 201 is laterally offset from the center C2 of the width for the source/drain regions 92. This misalignment can result in a back-side interconnect 200 being formed with a non-linear profile.

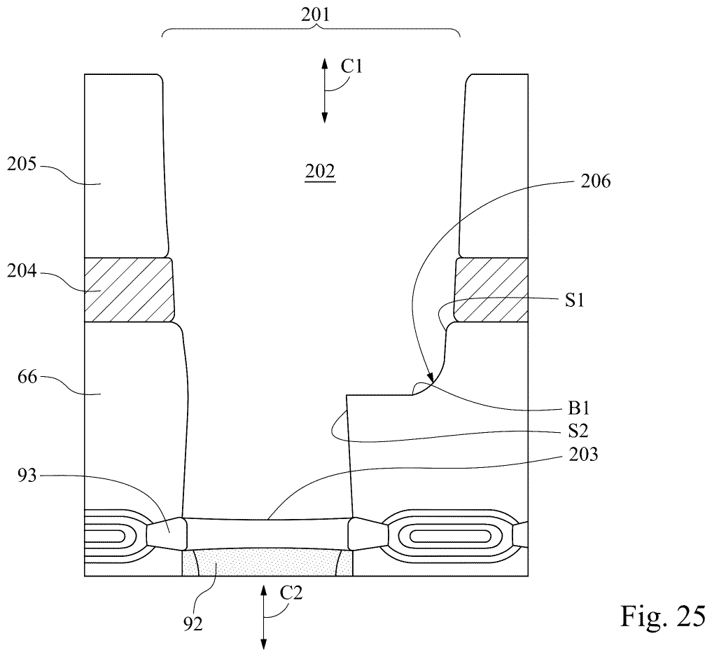

In FIG. 25, the first semiconductor layer 91 is removed exposing the back-side surface of the bottom spacer 93. In some embodiments, removing the first semiconductor layer 91 extends the contact opening 202 to a depth extending to the back-side surface of the bottom spacer 93, as illustrated in FIG. 25. In some embodiments, when the bottom spacers 93 is be composed of a nitride material, such as silicon nitride, and the first semiconductor layer 91 is composed of germanium containing composition, such as silicon germanium, and the first semiconductor layer 91 may be removed by an etch that is selective to the bottom spacer 93. For example, the etching process may etch the first semiconductor layer 91 at a faster rate than the bottom spacer 93 and a faster rate than the semiconductor fin 66. In some embodiments, when the depth of the via contact opening is extended to the bottom spacer 93 by removing the semiconductor layer 91, a portion of the sidewall for the contact opening 202 is exposed having a horizontally orientated portion or slanted portion (hereafter referred to as corner portion 206) that is between the contact aperture 201 and the base 203 of the contact opening 202.

The corner portion 206 in the sidewall of the contact opening 202 results from the lateral misalignment of the mask for defining the contact aperture 201 to the back-side of the epitaxial source/drain regions 92. The first semiconductor layer 91 is aligned to the epitaxial source/drain region 92. Because the center C1 of the width for the contact aperture 201 is laterally offset from the center C2 of the width for the epitaxial source/drain regions 92, when the first portion of the contact opening 202 is formed to the back-side of the first semiconductor layer 91, the center of the first portion of the contact opening 202 is laterally offset from the center of the first semiconductor layer 91. In the embodiment depicted in FIG. 25, the first portion of the contact opening 202 has a greater width than the first semiconductor layer 91, wherein a side portion of the first portion of the contact opening 202 extends past the outside edge of the first semiconductor layer 91. When the first semiconductor layer 91 is removed by the etch process that is selective to the semiconductor fin 66 to create the second portion of the contact opening 202, a horizontally orientated portion B1 of material of the semiconductor fin 66 is exposed between the sidewall S1 of the first portion of the contact opening 202 and the sidewall S2 of the second portion of the contact opening 202 resulting in the corner portion 206 in the sidewall of the contact opening 202.

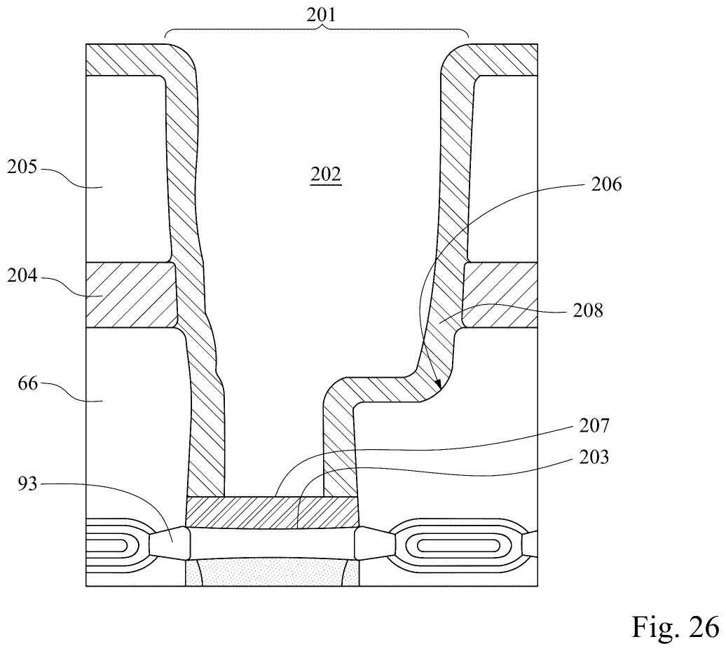

FIG. 26 illustrates an embodiment of forming an amorphous carbon fill within the contact opening 202 and recessing the amorphous carbon fill with an etch back process. In some embodiments, after the etch back process, a remaining portion of the amorphous carbon (α-C) fill provides an amorphous carbon layer 207 on the back-side surface of the bottom spacer 93. Amorphous carbon is a form of carbon with a disordered atomic structure, meaning it lacks a crystalline lattice like diamond or graphite. In some embodiments, the amorphous carbon may be amorphous hydrogenated carbon, α-C:H). In some embodiments, the amorphous carbon may be deposited to partially fill the contact opening 202 using a chemical vapor deposition (CVD) process. Variations of CVD processes suitable for depositing the amorphous carbon material include, but not limited to, Atmospheric Pressure CVD (APCVD), Low Pressure CVD (LPCVD) and Plasma Enhanced CVD (PECVD), Metal-Organic CVD (MOCVD) and combinations thereof may also be employed.

In some embodiments, an etch back process, such as a directional etch, e.g., reactive ion etching (RIE), may be used to recess the amorphous carbon fill, wherein a remaining portion of the amorphous carbon fill provides the amorphous carbon layer 207 that is present on the bottom spacer 93. The remaining portion of the amorphous carbon fill that provides the amorphous carbon layer 207 may have a thickness ranging from 2 nm to 10 nm. The amorphous carbon layer 207 covers the entire bottom spacer 93. Alternatively, the method for forming the amorphous carbon layer 207 may be a bottom up process, in which the material for the amorphous carbon layer 207 is only present at the base of the contact opening 202.

In another embodiment, prior to forming the amorphous carbon layer 207, the bottom spacer 93 may be etched extending the opening for the second portion of the contact opening 202 to the back-side of the epitaxial source/drain region 92. The bottom spacer 93 may be etched with reactive ion etching. In this embodiment, after the bottom spacer 93 is etched, the amorphous carbon layer may be formed directly on the back-side of the epitaxial source/drain region 92.

FIG. 26 also illustrates forming an aluminum containing dielectric layer 208 on the sidewalls of the contact opening 202 including the corner portion 206 of the sidewalls of the contact opening 202. In some embodiments, the aluminum containing dielectric layer 208 may be an aluminum containing oxide, such as aluminum oxide (Al2O3). It is further noted that the aluminum containing oxide may include elements of nitrogen. In some embodiments, the aluminum containing dielectric layer 208 may be formed using a conformal deposition process, such as atomic layer deposition (ALD). In some embodiments, the aluminum containing dielectric layer 208 has a lower growth rate on the amorphous carbon layer 207 than the surfaces that provide the sidewall of the contact opening 202. Therefore, the aluminum containing dielectric layer 208 is not substantially formed on the amorphous carbon layer 207 at the base of the contact opening 202. For example, the aluminum containing dielectric layer 208 may not be formed on the amorphous carbon layer 207 (as illustrated) or only a relatively thin layer of the aluminum containing dielectric layer 208 (e.g., thinner than portions formed on the sidewall of the contact opening 202) is formed on the amorphous carbon layer 207. The aluminum containing dielectric layer 208 is formed to be continuously present on the sidewalls of the contact opening 202 without breaks are voids.

In some embodiments, the conformally deposited aluminum containing dielectric layer 208 may have a thickness ranging from 2 nm to 5 nm. In some embodiments, the aluminum containing dielectric layer 208 is formed on the corner portions 206 of the sidewalls of the contact opening 202 to prevent the formation of the metal semiconductor alloys on the horizontally orientated portion or slanted portions of the contact opening sidewall during subsequent processing.

In FIG. 27, a back-side anti-reflective coating (BARC) fill 209 is formed filling the contact opening 202. The back-side anti-reflective coating (BARC) fill 209 may be deposited using a vacuum deposition technique, such as sputtering or chemical vapor deposition (CVD). Some examples of materials for the back-side anti-reflective coating (BARC) fill 209 can include titanium dioxide (TiO2). Other examples of the composition for the back-side anti-reflective coating (BARC) fill 209 can include silicon nitride. In some examples, the back-side anti-reflective coating (BARC) fill 209 may be deposited using atomic pressure chemical vapor deposition or spin on coating or spray coating.

FIG. 28 illustrates applying a directional etch to the back-side anti-reflective coating (BARC) fill 209. For example, the portions of the back-side anti-reflective coating (ARC) fill 209 that extend upward outside of the contact opening 202, and the portions of the aluminum containing dielectric layer 208 that extend outside of the contact opening 202 atop the upper surface of the first back-side dielectric layer 204 may first be removed by a directional etch, such as reactive ion etching (RIE).

FIG. 28 also illustrates applying oxygen ashing to remove the remainder of the back-side anti-reflective coating (BARC) fill 209. The oxygen ashing process removes the remainder of the back-side anti-reflective coating (BARC) fill 209 from the contact opening 202 including the portion that extends beneath the aluminum containing dielectric layer 208. Further, the oxygen ashing process removes the exposed portions of the amorphous carbon layer 207 producing a base opening exposing the back-side of the bottom spacer 93. Oxygen ashing removes organic materials. Oxygen ashing removes carbon using an oxygen plasma, which breaks down an organic material into volatile carbon oxides and water vapor. Both the back-side anti-reflective coating (BARC) fill 209 and the amorphous carbon layer 207 are carbon containing organics, while the aluminum containing dielectric layer 208 is an inorganic material that can be substantially carbon free. Because an aluminum containing dielectric layer 208, such as an aluminum oxide (Al₂O₃) layer is carbon free, the oxygen ashing process may remove the back-side anti-reflective coating (BARC) fill 209 and the amorphous carbon layer 207 without removing the aluminum containing dielectric layer 208.

FIGS. 29A and 29B illustrate forming protective spacers 300 on the aluminum containing dielectric layer 208 that is present on the sidewalls of the contact opening 202. In some embodiments, prior to depositing the material layers for forming the protective spacers 300, the bottom spacer 93 may be etched extending the opening for the second portion of the contact opening 202 to the back-side of the epitaxial source/drain region 92. The bottom spacer 93 may be etched with reactive ion etching. In some embodiments, the material layer for the protective spacers 300 may be deposited on the bottom spacer 93 at the base of the contact opening 202, wherein following etch processes to define the protective spacer 300, the bottom spacer 93 may then be etched to expose the back-side of the epitaxial source/drain region 92.

In some embodiments, the protective spacers 300 may be formed of a dielectric material, such as silicon nitride or the like, and formed by a deposition process, such as CVD, ALD, or the like. The material of the protective spacers 300 may also be formed on the aluminum containing dielectric layer 208. The protective spacers 300 may be formed using conformal deposition and anisotropic (directional) etch back process. The deposition process may include chemical vapor deposition (CVD) or atomic layer deposition (ALD). The material layer for the protective spacers 300 is deposited on the sidewall surfaces of the contact opening, the base surface of the contact opening and the upper surfaces of the second back-side dielectric layer 205. The material layer for the protective spacers 300 can fill the space between the aluminum containing dielectric layer 208 and the bottom spacer 93 that is formed when the amorphous carbon (α-C) is removed. The portions of the material layer for the protective spacers 300 that are present on the sidewalls of the contact opening are vertically orientated, while the portions of the material layer for the protective spacers 300 that are present on the base of the contact opening and the upper surfaces of the second back-side dielectric layer 205 are horizontally orientated. There may also be a horizontally orientated portion of the material layer for the protective spacers 300 on the corner portion 206 of the contact opening sidewall.

The etch process applied to the material layer for the protective spacers 300 may be a dry etching process utilizing etchants, such as fluoromethane, difluoromethane, nitrogen, hydrogen, combinations thereof, or the like. In some embodiments, the dry etching process is a directional etching process, such as reactive ion etching. The directional nature of the etch process removes the horizontally orientated portions of the deposited material layer for the protective spacers 300, such as the portions of the material layer for the protective spacers 300 at the base of the contact opening 202 and the portions of the material layer for the protective spacers 300 on the upper surfaces of the second back-side dielectric layer 205. The directional nature of the etching process can also remove the portion of the material layer for the protective spacers 300 that are present on the corner portions 206 of the contact opening sidewall. However, the aluminum containing dielectric layer 208 is present between the material layer for the protective spacers 300 and the corner portions 206 of the contact opening sidewall. The aluminum containing dielectric layer 208 protects the corner portions 206 of the contact opening sidewall during the etch processes applied to the material layer for the protective spacers 300. The aluminum containing dielectric layer 208 can stop semiconductor loss, e.g., the loss of silicon material from the substrate (portion of the substrate that provides the fin 66), at the corner portions 206 of the contact opening sidewall. Following the directional etch process, the protective spacers 300 are provided by the vertically orientated portions of the material layer that are not removed by the directional etch process. The contact spacers 300 may have thickness in a range of about 2 nm to about 5 nm. In some embodiments, following the etch process applied to the material layer for the protective spacers 300, a portion of the protective spacers 300 fill the space underlying the aluminum containing dielectric layer 208 that is created by removing the amorphous carbon (α-C). In some embodiments, the directional etch provides that the overlying aluminum containing dielectric layer 308 functions as an etch mask for the portion of the material of the protective spacers 300 that is present in the space created by removing the amorphous carbon. In some examples, the interior sidewall of the aluminum containing dielectric layer 308 and the interior sidewall of the underlying portion of the protective spacers 300 may be aligned to one another.

FIGS. 29A and 29B also depict etching through the bottom spacer 93 to provide an opening 319 exposing the back-side of the epitaxial source/drain regions 92 following the formation of the protective spacers 300. The bottom spacer 93 is etched by a directional etch process, such as reactive ion etching. As noted above, in an alternative embodiment, the bottom spacer 93 may have been etched prior to forming the material layers for the bottom spacer 93.

FIGS. 29A and 29B further depict implanting a p-type or n-type dopant into the exposed back-side surface of the epitaxial source/drain regions. The p-type or n-type dopant may be implanted using ion implantation. In some embodiments, the implantation of the p-type or n-type dopant at this stage of the process flow can increase conductivity for the region of the epitaxial source/drain regions 92 that are contacted by the back-side interconnect 200. For example, when the epitaxial source/drain regions 92 are doped with p-type dopant, the p-type impurities may be boron, boron fluoride, indium, or the like implanted into the back-side of the epitaxial source/drain region 92 to a concentration in a range from about 10¹³ atoms/cm³ to about 10¹⁴ atoms/cm³.

FIGS. 29A and 29B further illustrate forming a metal nitride layer 301 on the sidewalls of the contact opening and the base of the contact opening. The metal nitride layer 301 may be formed directly on the back-side surface of the epitaxial source/drain region 92 that is exposed by the opening 319 through the bottom spacer 93. The metal nitride layer 301 may be formed using chemical vapor deposition (CVD) or physical vapor deposition (PVD). In some embodiments, the metal nitride layer 301 may be composed of titanium nitride. However, in other embodiments, the metal nitride layer 301 may be composed of tantalum nitride, tungsten nitride, as well as other metal nitride compositions. The metal nitride layer 301 that is formed at the base of the contact opening can provide the metal for alloying with the epitaxial source/drain regions 92 in the formation of a metal semiconductor alloy region 302, e.g., silicide, on the back-side of the epitaxial source/drain regions 92. For example, the metal element of the metal nitride layer 301 may react with the semiconductor material of the epitaxial source/drain regions 92 (e.g., silicon, silicon germanium, germanium) to form silicide or germanide regions (metal semiconductor alloy region 302). In some embodiments, forming the metal semiconductor alloy, e.g., silicide and/or germanide, can include performing a thermal annealing process. In some embodiments, the thermal annealing process is performed at a temperate of about 450° C.

In some embodiments, although the aluminum containing dielectric layer 208 can mitigate semiconductor material loss, such as silicon loss, at the corner portion 206 of the contact opening sidewalls, if the corner portions 206 are compromised, any metal semiconductor alloy 304 formed at the corner portions 206 are still kept at a sufficient distance from the gate regions 400, as depicted in FIG. 29A. This can reduce the incidence of gate leakage. For example, the aluminum containing dielectric layer 208 can be damaged during etch processes to open the bottom spacer 93, which could expose semiconductor material from the substrate at the corner portions 206. During the formation of the metal semiconductor alloy region 302, the exposed portion of the semiconductor substrate at the corner portion 206 of the sidewall of the contact opening can alloy with metal elements used in forming the metal semiconductor alloy region 302 on the epitaxial source/drain region 92, which can product the metal semiconductor alloy 304 on the corner portions 206. It is noted that the metal semiconductor alloy 304 that is depicted in the corner portions 206 of the contact opening sidewall is depicted for illustrative purposes only. The aluminum containing dielectric layer 208 can protect the entire corner portion 206 of the contact opening sidewall, in which the formation of the metal semiconductor alloy 304 on the corner portion 206 of the contact opening sidewall can be completely eliminated, as depicted in FIG. 29B. For example, in some embodiments, in which the metal semiconductor alloy 304 is completely obstructed from being formed, the entire sidewall in the corner portion 206 will include the aluminum containing dielectric layer 208.

FIGS. 29A and 29B also illustrate a metal fill 303 (also referred to as plug fill) being formed within the contact opening. In some embodiments, the metal fill 303 may be composed of tungsten. However, in other embodiments, the conductive material for the metal fill 303 can be provided by at least one of cobalt, ruthenium, a combination of titanium, titanium nitride, and tungsten, or the like. In some embodiments, the metal nitride layer 301 can function as an adhesion layer for the metal fill 303. The material of the metal fill 303 may be formed by a deposition process, a plating process, or the like. Then a planarization process, such as CMP, may be performed to remove excess conductive material and the second back-side dielectric layer 205.

In FIGS. 29A and 29B, a device is depicted including an epitaxial source/drain region 92 including a metal semiconductor alloy region 302. The interconnect 200 depicted in FIGS. 29A and 29B contacts the metal semiconductor alloy region 302 of the epitaxial source/drain region 92. In some embodiments, the protective spacer 300 is on a first portion (lower portion) of a sidewall of the contact opening, and the protective spacer 300 is contacting the metal semiconductor alloy region 302 of the epitaxial source/drain region 92. In some embodiments, the aluminum containing dielectric layer 208 includes a portion that is atop the protective spacer 300 and on a second portion (higher portion) of the sidewall of the contact opening. For example, a portion of the aluminum containing dielectric layer 308 is stacked atop a portion of the protective spacer 300. The portion of the contact opening sidewall that the aluminum containing dielectric layer 208 is present on includes the corner portions 206 of the contact opening sidewall.

In some embodiments, the device further include a metal nitride liner (also referred to as metal nitride layer 301) contacting the metal semiconductor alloy region 302 of the epitaxial source/drain region 92, and the metal nitride layer 301 is also adjacent to the nitride protective spacer 300 and the aluminum containing dielectric layer 308. By adjacent it is meant that the metal nitride layer 301 is abutting the sidewall of the nitride protective spacer 300 and is abutting the sidewall of the aluminum containing dielectric layer 308, in which the aluminum containing dielectric layer 308 is stacked atop the protective nitride spacer 300. In some embodiments, the metal nitride layer 301 is between a stack of the nitride protective spacer 300 and the aluminum containing dielectric layer 208, and a metal fill 303 for the interconnect 200.

It is noted that the process flow described above with reference to FIGS. 1-29B is provided for illustrative purposes only. Changes in the order of the process flow are within the scope of the present disclosure, which can include a process flow in which the protective spacers 300 are formed prior to the formation of the aluminum containing dielectric layer 208, as depicted in FIG. 30. The protective spacers 300 may be formed of a dielectric material, such as silicon nitride or the like. In this example, the aluminum containing dielectric layer 208 protects the corner portions 206 of the contact opening sidewall during the etch processes for etching through the bottom spacer 93 prior to forming the metal semiconductor alloy region 302 on the back-side of the epitaxial source/drain 92.

In an embodiment, a method that includes forming a contact opening through a semiconductor substrate that is overlying a source/drain region; forming an aluminum containing dielectric layer on a corner section of the contact opening; forming a protective liner on the aluminum containing dielectric layer within the contact opening; etching the protective liner to form protective spacers within the contact opening, wherein the aluminum containing dielectric layer protects the semiconductor substrate from being exposed at the corner section of the contact opening during the etching of the protective liner; and forming a metal semiconductor alloy on the source/drain region at a base of the contact opening. In an embodiment, the contact opening has a non-linear profile when viewed from a side cr0ss-sectional view, wherein the non-linear profile includes a sidewall with the corner section. In an embodiment, the aluminum containing dielectric layer comprises aluminum oxide. In an embodiment, the forming of the aluminum containing dielectric layer includes forming an amorphous dielectric on the source/drain region at the base of the contact opening, and selectively forming the aluminum containing dielectric layer on a portion of the sidewall of the contact opening that extends from an aperture to the contact opening at a back-side of the semiconductor substrate to the amorphous dielectric. In an embodiment, the amorphous dielectric includes amorphous carbon. In an embodiment, the forming of the protective liner includes conformally depositing a material layer for the protective liner on the base of the contact opening, and on the aluminum containing dielectric layer that is on the sidewall of the contact opening; and etching the material layer for the protective liner with a directional etch that removes the material layer on the base of the contact opening, wherein the material layer for the protective liner remains on the aluminum containing dielectric layer that is on the sidewall of the contact opening. In an embodiment, forming the metal semiconductor alloy includes forming a metal nitride layer on the source/drain region at the base of the contact opening and alloying metal elements from the metal nitride layer with semiconductor elements from the source/drain region.

In another embodiment, a method including forming a source/drain region on a dielectric spacer, wherein the dielectric spacer is overlying a semiconductor substrate; forming a contact opening through the semiconductor substrate exposing a portion of the dielectric spacer; forming an amorphous dielectric on the dielectric spacer at a base of the contact opening; selectively forming an aluminum containing dielectric layer on a portion of a sidewall of the contact opening from an aperture to the contact opening at a back-side of the semiconductor substrate to the amorphous dielectric, wherein the amorphous containing dielectric layer is on a corner section of a sidewall of the contact opening; etching the amorphous dielectric and the dielectric spacer to expose a portion of the source/drain region; and forming a metal semiconductor alloy on the source/drain region. In an embodiment, the aluminum containing dielectric layer includes aluminum oxide. In an embodiment, the aluminum containing dielectric layer protects the semiconductor substrate at the corner of the sidewall of the contact opening from being exposed during etching of the dielectric spacer. In an embodiment, during the etching of the dielectric spacer a portion of the aluminum containing dielectric layer is removed to provide an exposed portion of the semiconductor substrate on the corner section of the sidewall of the contact opening, and during the forming of the metal semiconductor alloy for the source/drain region, the exposed portion of the semiconductor substrate at the corner section of the sidewall of the contact opening is alloyed with metal elements. In an embodiment, the method further includes forming a silicon nitride protective spacer between the sidewall of the contact opening and the aluminum containing dielectric layer. In an embodiment, the method further includes implanting n-type dopant or p-type dopant into the source/drain region before forming the metal semiconductor alloy. In an embodiment, forming the metal semiconductor alloy comprises forming a metal nitride layer on the source/drain region and alloying metal elements from the metal nitride layer with semiconductor elements from the source/drain region.

In yet another embodiment, a device including a source/drain region including a metal semiconductor alloy region; an interconnect contacting the metal semiconductor alloy region of the source/drain region, the interconnect including a sidewall having a corner section; a nitride protective spacer along a first portion of the sidewall for the interconnect, the nitride protective spacer contacting the metal semiconductor alloy region of the source/drain region; and an aluminum containing dielectric layer over the nitride protective spacer, the aluminum containing dielectric layer being disposed along a second portion of the sidewall for the interconnect that is adjacent to the corner section. In an embodiment, the interconnect further includes a metal nitride liner that contacts the metal semiconductor alloy region of the source/drain region, wherein the metal nitride liner is adjacent to the nitride protective spacer and the aluminum containing dielectric layer. In an embodiment, the metal nitride liner is between a stack of the nitride protective spacer and the aluminum containing dielectric layer, and a metal fill for the interconnect. In an embodiment, the aluminum containing dielectric layer comprises aluminum oxide. In an embodiment, the aluminum containing dielectric layer covers the corner section of the interconnect. In an embodiment, the device further includes an interconnect metal semiconductor alloy at the corner section of the interconnect.

The embodiments of the present disclosure have some advantageous features. For example, semiconductor structures are provided with back-side interconnects, in which a conformally deposited aluminum containing dielectric layer obstructs the formation of metal semiconductor alloys (such as silicide materials) on the sidewalls of the contact openings containing the back-side interconnect. In some embodiments, the aluminum containing dielectric layer is used to prevent semiconductor loss at the sidewalls of the contact opening containing the interconnect during nitride containing liner etching. The aluminum containing dielectric layer protects corners on the sidewalls of the contact openings, preventing semiconductor breakage and reducing metal gate leak risks in large overlay scenarios.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a contact opening through a semiconductor substrate that is overlying a source/drain region;
forming an aluminum containing dielectric layer on a corner section of the contact opening;
forming a protective liner on the aluminum containing dielectric layer within the contact opening;
etching the protective liner to form protective spacers within the contact opening, wherein the aluminum containing dielectric layer protects the semiconductor substrate from being exposed at the corner section 206 of the contact opening during the etching of the protective liner; and
forming a metal semiconductor alloy on the source/drain region at a base of the contact opening.

2. The method of claim 1, wherein the contact opening has a non-linear profile when viewed from a side cross-sectional view, wherein the non-linear profile includes a sidewall with the corner section.

3. The method of claim 1, wherein the aluminum containing dielectric layer comprises aluminum oxide.

4. The method of claim 2, wherein the forming of the aluminum containing dielectric layer comprises:
forming an amorphous dielectric on the source/drain region at the base of the contact opening; and
selectively forming the aluminum containing dielectric layer on a portion of the sidewall of the contact opening that extends from an aperture to the contact opening at a back-side of the semiconductor substrate to the amorphous dielectric.

5. The method of claim 4, wherein the amorphous dielectric comprises amorphous carbon.

6. The method of claim 2, wherein the forming of the protective liner comprises:
conformally depositing a material layer for the protective liner on the base of the contact opening, and on the aluminum containing dielectric layer that is on the sidewall of the contact opening; and
etching the material layer for the protective liner with a directional etch that removes the material layer on the base of the contact opening, wherein the material layer for the protective liner remains on the aluminum containing dielectric layer that is on the sidewall of the contact opening.

7. The method of claim 1, wherein forming the metal semiconductor alloy comprises forming a metal nitride layer on the source/drain region at the base of the contact opening and alloying metal elements from the metal nitride layer with semiconductor elements from the source/drain region.

8. A method comprising:
forming a source/drain region on a dielectric spacer, wherein the dielectric spacer is overlying a semiconductor substrate;
forming a contact opening through the semiconductor substrate exposing a portion of the dielectric spacer;
forming an amorphous dielectric on the dielectric spacer at a base of the contact opening;
selectively forming an aluminum containing dielectric layer on a portion of a sidewall of the contact opening 202 from an aperture to the contact opening at a back-side of the semiconductor substrate to the amorphous dielectric, wherein the amorphous containing dielectric layer is on a corner section of a sidewall of the contact opening;
etching the amorphous dielectric and the dielectric spacer to expose a portion of the source/drain region; and
forming a metal semiconductor alloy on the source/drain region.

9. The method of claim 8, wherein the aluminum containing dielectric layer comprises aluminum oxide.

10. The method of claim 8, wherein the aluminum containing dielectric layer protects the semiconductor substrate at the corner of the sidewall of the contact opening from being exposed during etching of the dielectric spacer.

11. The method of claim 8, wherein during the etching of the dielectric spacer a portion of the aluminum containing dielectric layer is removed to provide an exposed portion of the semiconductor substrate on the corner section of the sidewall of the contact opening, and during the forming of the metal semiconductor alloy for the source/drain region, the exposed portion of the semiconductor substrate at the corner section of the sidewall of the contact opening is alloyed with metal elements.

12. The method of claim 8, further comprising forming a silicon nitride protective spacer between the sidewall of the contact opening and the aluminum containing dielectric layer.

13. The method of claim 8, further comprising implanting n-type dopant or p-type dopant into the source/drain region before forming the metal semiconductor alloy.

14. The method of claim 8, wherein forming the metal semiconductor alloy comprises forming a metal nitride layer on the source/drain region and alloying metal elements from the metal nitride layer with semiconductor elements from the source/drain region.

15. A device comprising:
a source/drain region including a metal semiconductor alloy region;
an interconnect contacting the metal semiconductor alloy region of the source/drain region, the interconnect including a sidewall having a corner section;
a nitride protective spacer along a first portion of the sidewall for the interconnect, the nitride protective spacer contacting the metal semiconductor alloy region of the source/drain region; and
an aluminum containing dielectric layer over the nitride protective spacer, the aluminum containing dielectric layer being disposed along a second portion of the sidewall for the interconnect that is adjacent to the corner section.

16. The device of claim 15, the interconnect further comprising a metal nitride liner that contacts the metal semiconductor alloy region of the source/drain region, wherein the metal nitride liner is adjacent to the nitride protective spacer and the aluminum containing dielectric layer.

17. The device of claim 16, wherein the metal nitride liner is between a stack of the nitride protective spacer and the aluminum containing dielectric layer, and a metal fill for the interconnect.

18. The device of claim 15, wherein the aluminum containing dielectric layer comprises aluminum oxide.

19. The device of claim 15, wherein the aluminum containing dielectric layer covers the corner section of the interconnect.

20. The device of claim 15, further comprising an interconnect metal semiconductor alloy at the corner section of the interconnect.
